(19) United States
(12) Patent Application Publication
(10) Pub. No.: US 2026/0068710 A1
(43) Pub. Date: Mar. 5, 2026

(54) INTER-DIE CONNECTIVITY TECHNIQUES WITH A BRIDGE DIE AND THROUGH-ASSEMBLY CONDUCTIVE VIAS

(71) Applicant: Intel Corporation, Santa Clara, CA (US)

(72) Inventors: Sagar Suthram, Portland, OR (US); Doug B. Ingerly, Portland, OR (US); Wilfred Gomes, Portland, OR (US); Pushkar Sharad Ranade, San Jose, CA (US); Abhishek A. Sharma, Portland, OR (US)

(73) Assignee: Intel Corporation, Santa Clara, CA (US)

(21) Appl. No.: 18/818,987

(22) Filed: Aug. 29, 2024

(51) Int. Cl. H01L 23/538; H01L 23/00; H01L 23/48; H01L 23/498; H01L 23/522; H01L 25/065; H01L 25/18; H05K 1/18

(52) U.S. Cl. CPC H01L 23/5386; H05K 1/181; H05K 2201/10734

(57) ABSTRACT

A microelectronic assembly with a bridge die and through-assembly conductive vias may enable higher performance connectivity of dies or die stacks. In one example, an assembly includes a first IC structure (e.g., a bridge die) over and coupled with a circuit board, a second IC structure (e.g., a substrate) over the first IC structure, and a plurality of coplanar dies or die stacks between and bonded with the first IC structure and the second IC structure. Conductive vias may be formed through the dies or die stacks after attaching the dies or die stacks to the first or second IC structures, where a conductive via through a die or die stack may extend through the die or die stack so that a first portion of the conductive via is coplanar with the side or face of the die or die stack that is bonded with the first IC structure.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B are cross-sectional diagrams of examples of microelectronic assemblies including a bridge die and through-assembly conductive vias, in accordance with some embodiments.

FIG. 1C is a diagram of an example IC structure that may be included in an assembly with a bridge die and through-assembly conductive vias, in accordance with some embodiments.

FIG. 1D is a diagram of a die that may be, or be included in, an IC structure of an assembly that includes a bridge die and through-assembly conductive vias, in accordance with embodiments.

FIG. 1E is a diagram of an assembly with a bridge die and through-assembly conductive vias, in accordance with embodiments.

FIGS. 2A-2F are cross-sectional diagrams of different examples of assemblies including a bridge die and through-assembly conductive vias, in accordance with some embodiments.

FIGS. 3A-3B illustrate cross-sectional views of microelectronic assemblies including a bridge die and through-assembly conductive vias, in accordance with some embodiments.

FIG. 4 is a flow diagram of an example method for fabricating a microelectronic assembly including a bridge die and through-assembly conductive vias, in accordance with some embodiments.

FIGS. 5A-5E provide cross-sectional side views at various stages in the fabrication of an example assembly according to the method of FIG. 4, in accordance with some embodiments.

FIG. 6 is a flow diagram of an example method for fabricating a microelectronic assembly including a bridge die and through-assembly conductive vias, in accordance with some embodiments.

FIGS. 7A-7D provide cross-sectional side views at various stages in the fabrication of an example assembly according to the method of FIG. 6, in accordance with some embodiments.

FIG. 8 is a top view of a wafer and dies that may include any of the IC devices disclosed herein, in accordance with any of the embodiments disclosed herein.

FIG. 9 is a side, cross-sectional view of an IC package that may include any of the IC devices disclosed herein, in accordance with various embodiments.

FIG. 10 is a side, cross-sectional view of an IC device assembly that may include any of the IC devices disclosed herein, in accordance with any of the embodiments disclosed herein.

FIG. 11 is a block diagram of an example electrical device that may include any of the IC devices disclosed herein, in accordance with any of the embodiments disclosed herein.

### DETAILED DESCRIPTION

Disclosed herein are inter-die connectivity techniques and microelectronic assemblies with a bridge die and conductive vias through the assembly. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Semiconductor chip manufacturing involves a series of complex processes to create IC structures. These processes include photolithography, ion implantation, etching, and deposition. A wafer typically goes through multiple rounds of these processes to form devices and interconnects on the wafer. Once the wafer processing is complete, the wafer may be cut into individual chips (also called dies). After dicing, the individual dies are packaged to provide interconnections with other components and protection.

Packaging the dies may involve attaching the dies to a substrate (such as a motherboard, interposer, or other circuit board or structure with conductive interconnects) to connect the die's conductive contacts to the package's conductive contacts (e.g., with flip chip bonding, ball grid array (BGA), etc.). For attachment to a circuit board, a die may be soldered directly onto the board or inserted into a socket (e.g., in the case of a packaged die). In some cases, multiple dies may be combined (e.g., stacked) into a single assembly or package before being mounted on the circuit board.

Two dies or die stacks on a circuit board may communicate with one another through conductive interconnects in the circuit board and through pads and bumps at the interface between the circuit board and the dies or die stacks. Thus, conductive lines and vias in each of the dies or die stacks typically end on the bumps at the interface between the circuit board and the dies. The bumps at the interface between the dies and the circuit board can be a limiting factor with regards to performance, power delivery, and thermal management. For example, solder bumps may prevent high frequency signaling at the interface with the bumps (e.g., due to signal distortion and crosstalk). Solder bumps may also limit power delivery through an interface with solder bumps due to the limited current carrying capacity of solder bumps and the risk of electromigration in solder bumps at high current densities. Solder bumps at the interface may also pose challenges for thermal management (e.g., due to limitations in the thermal conductivity of solder bumps).

According to examples described herein, a microelectronic assembly may include a bridge die and through-assembly conductive vias to couple dies or die stacks with one another. In one example, an assembly includes a first IC structure (e.g., a bridge die), a second IC structure (e.g., a substrate) over the first IC structure, and a plurality of coplanar dies or die stacks between and bonded with the first IC structure and the second IC structure. Conductive vias may be formed through the dies or die stacks after attaching the dies or die stacks to the first or second IC structures, where a conductive via through a die or die stack may extend through (e.g., entirely through or substantially entirely through) the die or die stack so that a first portion of the conductive via is coplanar with the side or face of the die or die stack that is bonded with the first IC structure, and a second portion of the conductive via is coplanar with the side or face of the die or die stack that is bonded with the second IC structure. The conductive vias may be coupled with conductive elements in the first IC structure and/or the second IC structure, which may enable a coupling the different dies or die stacks between the first and second IC structures. In some examples, the conductive vias may extend through one or more interfaces that include conductive bumps (e.g., without terminating on the bumps) to enable higher performance and/or higher density connections.

IC structures as described herein, in particular IC structures and assemblies including a bridge die and through-assembly conductive vias, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures and assemblies including a bridge die and through-assembly conductive vias as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified.

Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

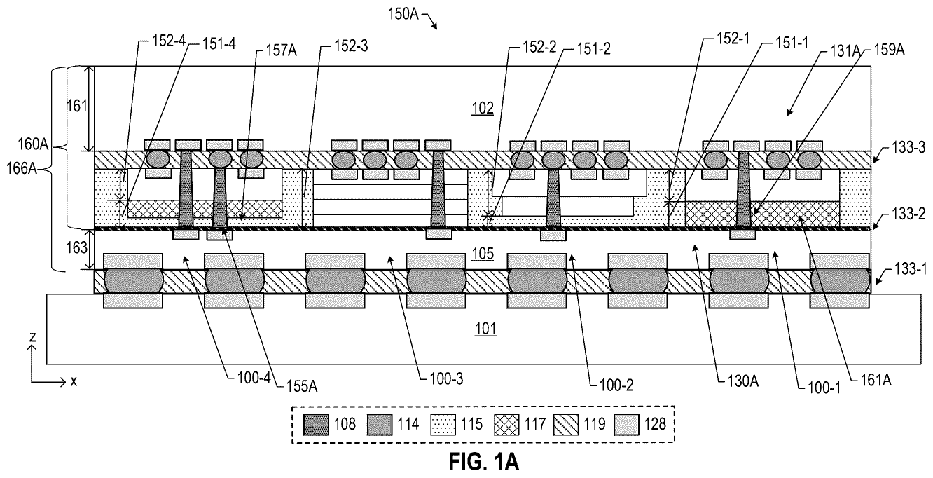

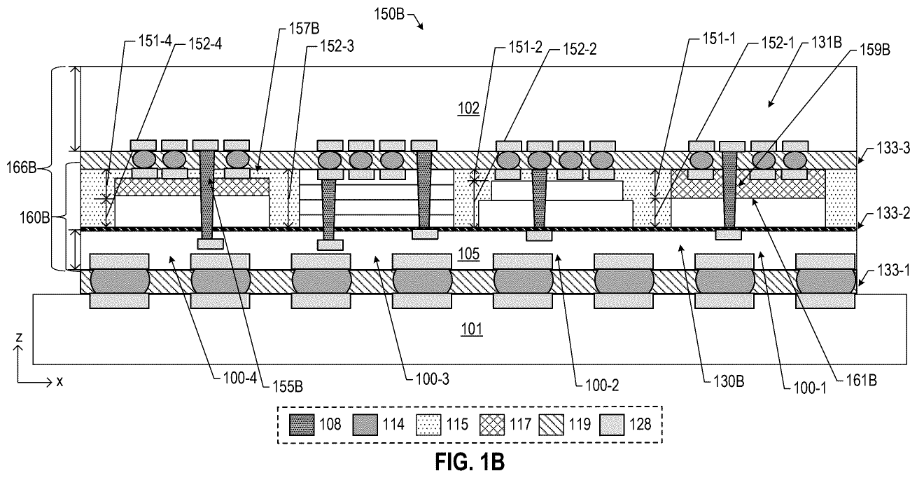

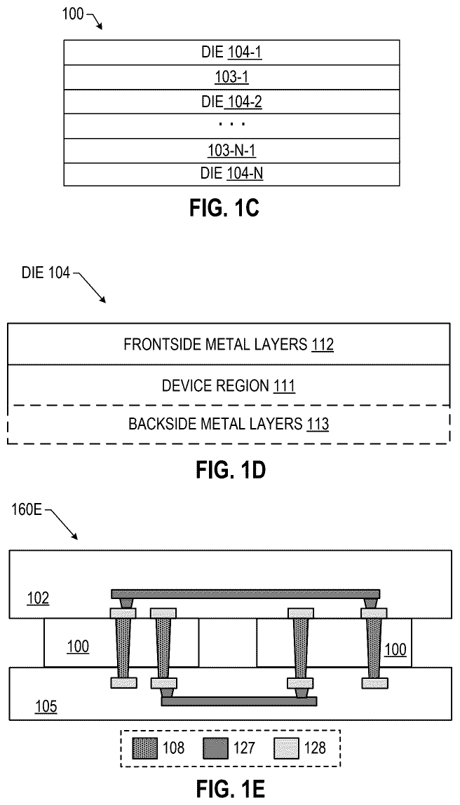

FIGS. 1A-1B are cross-sectional diagrams of examples of microelectronic assemblies 150A and 150B including a bridge die 105 and through-assembly conductive vias 108, in accordance with some embodiments. A number of elements referred to in the description of FIGS. 1A-1B, 1E, 2A-2F, 3A-3B, 5A-5E, and 7A-7D, with reference numerals are illustrated in these drawings with different patterns, with a legend showing the correspondence between the reference numerals and patterns being provided at the bottom of each drawing page containing FIGS. 1A-1B, 1E, 2A-2F, 3A-3B, 5A-5E, and 7A-7D. For example, the legend illustrates that FIGS. 1A-1B use different patterns to show a conductive via 108 and a conductive bump 114, and so on.

The assemblies 150A, 150B include IC structures 100-1, 100-2, 100-3, and 100-4 that are bonded with and between a substrate 102 and a bridge die 105, which is bonded with a circuit board 101. The different IC structure 100-1-100-4 are coplanar (e.g., at least some portion of each of the IC structures 100-1-100-4 is in the same plane, where the plane is parallel with the substrate 102). Although FIGS. 1A-1B depict assemblies 150A, 150B that include four IC structures, fewer than or more than four IC structures may be bonded between the substrate 102 and the bridge die 105. Each of the IC structures 100-1-100-4 depicted in FIGS. 1A-1B includes one or more dies. FIG. 1C illustrates an example of an IC structure 100. The IC structure 100 shown in FIG. 1C includes a plurality of N dies 104-1-104-N(of which dies 104-1, 104-2, and 104-N are shown) stacked over and bonded with one another, where N is a positive integer greater than or equal to two.

A plurality of dies stacked over one another may be referred to as a die stack. In some examples, the number of dies 104-1-104-N in a die stack may be, e.g., two, three, four, eight, or some other positive integer greater than or equal to two. In practice, the number of dies 104-1-104-N stacked over one another in a die stack may be limited by a variety of factors, including challenges related to thermal management and connectivity. Although a stack of multiple dies 104-1-104-N is shown in FIG. 1C, in some examples, IC structures may include a single die (e.g., a single active die including logic and/or memory devices). The dies 104-1-104-N may be the same type of die, or may include different types of dies. For example, one or more of the dies 104-1-104-N may include compute logic (e.g., a processor die, an accelerator die, or other die with compute logic), a memory die, a die with both compute logic and memory, or another type of die. The example in FIG. 1C depicts a plurality of dies 104-1-104-N having the same dimensions (e.g., the same width, length, and thickness), however, the dies in a stack of dies may have the same or different dimensions. The IC structure 100 may include interfaces 103-1-103-N−1 between adjacent dies of the IC structure 100 (e.g., between vertically adjacent stacked dies). The interfaces 103-1-103-N−1 may include any suitable interface (e.g., a hybrid bonding interface, an interface including conductive bumps such as BGA, or other interface).

Each one of the dies 104-1-104-N may include a device region and conductive interconnect layers. For example, FIG. 1D shows a diagram of a die 104 with a device region 111, frontside metal layers 112 over the device region, and backside metal layers 113. The device region includes devices formed over a substrate, and may include or be referred to as a front end of line (FEOL) layer. The device region 111 may include frontend devices (e.g., frontend transistors such as FinFETs, nanowire/nanoribbon transistors, frontend memory cells, or other frontend devices). The frontside metal layers 112 are over a front side of the device region, and the backside metal layers 113 are over a back side of the device region. The metal layers 112, 113 may also be referred to as back end of line (BEOL) layers. Various metal layers 112, 113 may be used to interconnect the various inputs and outputs of the devices (e.g., logic devices or memory devices) in the device regions 111. In one example, each of the metal layers may include vias and lines/trenches, as discussed in further detail below. The metal layers 112, 113 may also include devices (e.g., backend devices). Some dies may include more, fewer, and or different layers/regions than shown in FIG. 1C. For example, some dies may have only a device region and frontside metal layers 112, but lack backside metal layers. Other dies may lack a device region (e.g., an interconnect die).

Referring again to FIGS. 1A-1B, the IC structures 100-1-100-4 are disposed between the bridge die 105 and the substrate 102, and bonded with the bridge die 105 and the substrate 102 via interfaces 133-2 and 133-3, respectively. The bridge die 105 is bonded with the circuit board 101 via the interface 133-1. The IC structures 100-1-100-4 may be bonded with the substrate 102 and bridge die 105 in accordance with any suitable bonding technique. The examples in FIGS. 1A-1B depict the interface 133-1 between the circuit board 101 and the bridge die 105 as including conductive bumps 114, the interface 133-2 between the bridge die 105 and the IC structures 100-1-100-4 as including a hybrid bonding interface, and the interface 133-3 as including conductive bumps 114. Also as illustrated in the examples of FIGS. 1A-1B, the interface 103-1 between the circuit board 101 and the bridge die 105 may have conductive bumps 114 with a larger pitch and width than conductive bumps at an interface between the IC structures 100-1-100-4 and the bridge die 105 (when present), between the IC structures 100-1-100-4 and the substrate 102, or between dies of a die stack (e.g., the conductive bumps 114 of the interface 103-1). Other examples may include different interfaces than those depicted in FIGS. 1A-1B (e.g., the IC structures 100-1-100-4 may be bonded with the bridge die 105 via an interface with conductive bumps 114).

An interface with conductive bumps may include a plurality of coplanar bumps between the two bonded IC structures (e.g., between two dies of an IC structure, between an IC structure and the substrate 102, between an IC structure and the bridge die 105, etc.). The conductive bumps 114 are typically coupled with conductive elements, such as conductive pads 128. For example, in FIGS. 1A-1B, each of the conductive bumps 114 of the interfaces 133-1 and 133-3 is between two conductive pads 128, or between a conductive pad and a conductive via 108. In some examples, the bumps may be arranged in an array, such as in BGA assemblies. Conductive bumps may be formed to have various shapes (e.g., spherical/round, cylindrical, etc.), which may be deformed after bonding. Conductive bumps include a conductive material (e.g., one or more metals), such as solder, copper, gold, or other suitable conductive material. Conductive bumps that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of conductive bumps may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

In some examples, the conductive bumps 114 are surrounded by an insulator material 119 (sometimes referred to as a filler or underfill material) in a plane with the conductive bumps. The insulator material 119 may be provided according to any suitable method (e.g., deposited before or after formation of the bumps), and may provide mechanical support to an interface layer with conductive bumps 114. The insulator material 119 may be any suitable insulator material, such as silicon oxide, silicon carbide, silicon oxynitride, carbon-doped silicon oxide, spin-on-glass, boron-doped silicon oxide, an organic polymer, carbon, a carbon polymer, or any other suitable insulator material.

Another technique for bonding two IC structures, such as two dies, is hybrid bonding. For example, the IC structures 100-1-100-4 are hybrid bonded (e.g., without intervening conductive bumps) with the bridge die 105. In hybrid bonding, the bonding process is between a first layer of a first IC structure and a second layer of a second IC structure and also between conductive structures within the first layer and conductive structures within the second layer. For example, in hybrid bonding, a conductive structure (e.g., a via including metal) extends through each of the first and second layers, prior to these layers being bonded to form the bonding interface layer. For example, a first interconnect structure extends through the first layer and is exposed through, and flush with, a surface of the first layer; and a second interconnect structure extends through the second layer and is exposed through, and flush with, a surface of the second layer (e.g., prior to the bonding process). During the bonding process, surfaces of the first layer and the second layers bond to form a bonding interface layer, along with a bonding or contact of the first interconnect structure and the second interconnect structure. The interconnect structures in adjacent stacked dies that are bonded together may be, for example, conductive vias, conductive pads, or any other suitable conductive elements that may be bonded together via a hybrid bonding process. For example, some or all of the conductive vias 108 of FIG. 1A may be bonded with corresponding pads 128 of the bridge die 105. In one example, due to unintentional practical considerations of the bonding process, the conductive interconnects of the first and second layers may not be perfectly aligned during the bonding process. Accordingly, sections of a combined interconnect structures formed through a hybrid bonding process, which extend through the bonding interface layer, may have some misalignment or offset.

Hybrid bonding may involve bonding a front side of one die to a back side of another die (e.g., “front-to-back”), bonding the back side of one die to the back side of another die (e.g., “back-to-back”), or bonding the front side of one die to the front side of another die (e.g., “front-to-front”). The side of a substrate on which a device layer is provided is typically referred to as a front side, and the other side of the substrate is referred to as a back side.

In some embodiments, hybrid bonding may be performed using insulator-insulator bonding, e.g., as oxide-oxide bonding, where an insulator material of one die is bonded with the insulator material of another die. In some embodiments, a bonding material may be present in between the faces that are bonded together. To that end, the bonding material may be applied to the one or both faces that are to be bonded and then the faces are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the faces of different IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using, at a bonding interface, an etch-stop material that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond.

In some embodiments, no bonding material may be used, but there will still be a bonding interface resulting from the hybrid bonding. Such a bonding interface may be recognizable as a seam or a thin layer in the microelectronic assembly, using, e.g., selective area diffraction (SED), even when the specific materials of the insulators of the layers that are bonded together may be the same, in which case the bonding interface would still be noticeable as a seam or a thin layer in what otherwise appears as a bulk insulator (e.g., bulk oxide) layer.

In some examples, one or more of the IC structures 100-1-100-4 may include an interconnect die between adjacent stacked dies of the IC structure, and/or between the IC structure and the substrate 102 or bridge die 105. An interconnect die includes primarily, or exclusively, conductive interconnects, and may be thinner than a die with both a device region and interconnect layers. In some examples, an interconnect die may lack devices such as transistors. In other examples, the interconnect die may have some devices (e.g., switches) for signal routing purposes, but lack compute logic devices. In one example, an interconnect die may be hybrid bonded with dies on either side of the interconnect die.

The substrate 102 may include a structure that includes conductive interconnects, a structure that provides mechanical stability and support, or a structure that provides both conductive interconnects and mechanical support. In one example, the substrate 102 may be an interposer, interconnect die or structure, or other IC structure including conductive interconnects that are coupled with conductive interconnects in one or more of the IC structures 100-1-100-4. Conductive interconnects in the substrate 102 may include conductive traces (e.g., lines) and vias. For example, FIG. 1E illustrates an example assembly 160E in which the substrate 102 includes conductive interconnects 127 coupled with through-assembly conductive vias 108. In one such example, the substrate 102 includes primarily conductive interconnects without compute logic (e.g., compute logic may be absent from the substrate 102). In other examples, the substrate 102 may be primarily or entirely a support structure without conductive interconnects coupled with the IC structures 100-1-100-4.

In one example, the substrate 102 includes an insulating material (e.g., a dielectric material formed in multiple interconnect layers, as known in the art). In some embodiments, the insulating material of the substrate 102 may be a dielectric material, such as an organic dielectric material, a fire retardant grade 4 material (FR-4), bismaleimide triazine (BT) resin, polyimide materials, glass reinforced epoxy matrix materials, or low-k and ultra-low-k dielectric (e.g., carbon-doped dielectrics, fluorine-doped dielectrics, porous dielectrics, and organic polymeric dielectrics). The insulator material of the substrate may include any suitable interlayer dielectric (ILD) material for providing electrical isolation between portions of the substrate 102. In various embodiments, the insulator material may include materials such as silicon oxide, carbon-doped silicon oxide, silicon carbide, silicon nitride, silicon oxynitride, aluminum oxide, organic polymers such as perfluorocyclobutane or polytetrafluoroethylene, fluorosilicate glass (FSG), and organosilicates such as silsesquioxane, siloxane, or organosilicate glass. In particular, when the substrate 102 is formed using standard printed circuit board (PCB) processes, the substrate 102 may include FR-4, and the conductive pathways in the package substrate 102 may be formed by patterned sheets of copper separated by buildup layers of the FR-4. In examples where the substrate 102 is formed using semiconductor fabrication processes, the insulator material of the substrate may include, e.g., one of the ILDs mentioned above.

According to some examples, the bridge die 105 is an IC structure with conductive interconnects (e.g., metal lines and vias) that provide a conductive path amongst the different IC structures 100-1-100-4 and other components. For example, FIG. 1E illustrates an example in which the bridge die includes conductive interconnects 127 coupled with through-assembly conductive vias 108. The bridge die 105 may also be referred to as an interconnect die, an interconnect structure, or an IC structure. In one example, the bridge die 105 includes an insulating material (e.g., a dielectric material formed in multiple interconnect layers, as known in the art). In some examples, the bridge die 105 may include transistors configured as switches to enable configurable routing on the bridge die 105. In other examples, transistors may be absent from the bridge die 105 (e.g., the bridge die 105 may include only conductive interconnects without switching logic). The bridge die 105 may accommodate different connection pitches between the IC structures 100-1-100-4 and the circuit board 101. For example, the bridge die 105 may include fine-pitch conductive contacts on one side or face to match the IC structures 100-1-100-4 and larger-pitch conductive contacts on the opposite side or face to match the conductive contacts on the circuit board 101. Using fanout designs and redistribution layers, bridge dies can spread out and reroute dense chip connections to a larger area, enabling the transition from fine to coarse pitch.

Thus, in some examples, the substrate 102 and the bridge die 105 may be similar structures in the sense that they may both include interconnect layers including conductive interconnects that are coupled with one or more of the IC structures 100-1-100-4. However, in the examples illustrated in FIGS. 1A and 1B, the bridge die 105 includes larger pitch conductive contacts for attaching to the motherboard (e.g., between the circuit board 101 and the IC structures 100-1-100-4), whereas the substrate 102 may include finer pitch conductive contacts, or may lack conductive contacts. Additionally, the bridge die 105 in FIGS. 1A and 1B is attached to the motherboard, whereas the substrate 102 is bonded with the IC structures 100-1-100-4 (but not attached to the circuit board 101). In one example, both the bridge die 105 and the substrate 102 may include conductive interconnects, however, the bridge die 105 may include more interconnects (e.g., more metal layers and/or more conductive interconnects in a given metal layer) than the substrate 102. In one example, regardless of the number of interconnect layers or interconnects present in the substrate 102 and the bridge die 105, the substrate may have a greater thickness 161 (e.g., to provide more mechanical support to the assemblies 150A, 150B) than the thickness 163 of the bridge die 105. For example, the bridge die 105 may include only or primarily metal layers, and may be thinned (which can reduce capacitance and the thickness of the resulting assemblies 150A, 150B).

The bridge die 105, substrate 102, and IC structures 100-1-100-4 may be enclosed in a package and attached to the circuit board 101. The circuit board 101 may be a PCB, such as a motherboard, and typically includes other IC structures and/or components attached to it (not shown in FIGS. 1A-1B). The circuit board 101 may include conductive pathways and other conductive contacts (not shown) for routing power, ground, and signals through the circuit board 101 to the IC structure 100 and other IC structures attached to the circuit board 101, as known in the art. The circuit board 101 may include connectors (e.g., slots, sockets, ports, etc.) for coupling a variety of components to a computing system (e.g., processors, memory, etc.).

The assemblies 150A, 150B also include a plurality of conductive vias 108 extending through the IC structures 100-1-100-4. The conductive vias 108 may be used for transmitting data signals, power, ground, or for providing thermal channels. In some examples, the conductive vias 108 include one or more of copper, tungsten, titanium nitride, ruthenium, molybdenum, tungsten nitride, copper aluminum, or any other suitable conductive material. In the examples illustrated in FIGS. 1A-1B, each of the conductive vias is coupled with conductive elements, such as a conductive pad 128 (which may be referred to as a bond pad, contact pad, or landing pad), a conductive bump 114, or other conductive contact or conductive element. The conductive pads 128 include a conductive material, such as one or more of copper, silver, gold, molybdenum, alloys thereof, and/or other metals. The plurality of conductive vias 108 may be formed after attaching the IC structures 100-1-100-4 to the bridge die 105 (e.g., as shown in FIG. 1B) or after attaching the IC structures 100-1-100-4 to the substrate 102 (e.g., as shown in FIG. 1A). Thus, FIG. 1A depicts an assembly 160A that includes the IC structures 100-1-100-4 and the substrate 102, and FIG. 1B depicts an assembly 160B that includes the IC structures 100-1-100-4 and the bridge die 105. In FIG. 1A, the assembly 160A may then be bonded with the bridge die 105 to form an assembly 166A. Similarly, in FIG. 1B, the assembly 160B may then be bonded with the substrate 102 to form an assembly 166B. The assemblies 166A or 166B may then be bonded or otherwise attached to the circuit board 101. Any suitable technique, such as hybrid bonding, wire bonding, or bonding with a plurality of conductive bumps may be used to bond the various structures of FIGS. 1A and 1B.

FIG. 1A illustrates an example of an assembly 150A in which the conductive vias 108 are formed through the IC structures 100-1-100-4 after attaching the IC structures 100-1-100-4 to the substrate 102. The bridge die 105 may then be attached to the other side of the IC structures 100-1-100-4 (e.g., to the assembly 160A) after forming the vias 108 (and after flipping over the structure), to couple the vias 108 to conductive contacts of the bridge die 105. Thus, one side or face of each of the IC structures 100-1-100-4 is bonded with the substrate 102, and the opposite side or face of the IC structures 100-1-100-4 (e.g., the side or face of the assembly 160A opposite the substrate 102) may be bonded with the bridge die 105. For example, the IC structure 100-1 of FIG. 1A has a first face or side 130A that faces and may be bonded with the bridge die 105, and a second face or side 131A that faces and may be bonded with the substrate 102. Furthermore, due to first attaching the IC structures 100-1-100-4 to the substrate 102 and then forming the vias 108 through the IC structures 100-1-100-4, the plurality of conductive vias 108 of FIG. 1A taper in a direction from the bridge die 105 towards the substrate 102, and may extend completely through the IC structures 100-1-100-4 (and in some examples, through the interface 133-3) to couple with conductive elements of the substrate 102. Thus, the plurality of conductive vias 108 shown in FIG. 1A start at or are proximate to the interface 133-2 with the bridge die 105 (e.g., in/at the interface 133-2 or in/at a metal layer of dies of the IC structures 100-1-100-4 that are closest to the bridge die 105) and end in/at or proximate to the interface 133-3 with the substrate 102 (e.g., in/at the interface 133-3 or in/at a metal layer of dies of the IC structures 100-1-100-4 that are closest to the substrate).

In contrast, FIG. 1B illustrates an example of an assembly 150B in which the conductive vias 108 are formed through the IC structures 100-1-100-4 after attaching the IC structures 100-1-100-4 to the bridge die. The substrate 102 may then be attached to the other side of the IC structures 100-1-100-4 (e.g., to the side or face of the assembly 160B that is furthest from the bridge die 105) after forming the vias 108, to provide mechanical support and/or interconnection between conductive vias 108. Thus, one side or face of each of the IC structures 100-1-100-4 is bonded with the bridge die 105, and the opposite side or face of each of the IC structures 100-1-100-4 (e.g., the side or face of the assembly 160B furthest from the bridge die 105) is bonded with the substrate 102. For example, the IC structure 100-1 of FIG. 1B has a first face or side 130B that faces and may be bonded with the bridge die 105, and a second face or side 131B that faces and may be bonded with the substrate 102. Furthermore, due to first attaching the IC structures 100-1-100-4 to the bridge die 105 and then forming the vias 108 through the IC structures 100-1-100-4, the plurality of conductive vias 108 of FIG. 1B taper in a direction from the substrate 102 towards the bridge die 105, and may extend completely through the IC structures 100-1-100-4 (and in some examples, through the interface 133-2) to couple with conductive elements of the substrate 102. Additionally, some of the conductive vias 108 of FIG. 1B extend through the interface 133-2 and into the bridge die 105. Thus, the plurality of conductive vias 108 shown in FIG. 1B start at or are proximate to the interface 133-3 with the substrate 102 (e.g., in/at the interface 133-3 or in/at a metal layer of dies of the IC structures 100-1-100-4 that are closest to the substrate 102) and end in/at or proximate to the interface 133-2 (e.g., in/at the interface 133-2 or in/at a metal layer of dies of the IC structures 100-1-100-4 that are closest to the substrate) or in a layer of the bridge die 105.

Unlike in conventional assemblies, in some examples, at least one of the conductive vias 108 may pass through an interface with conductive bumps. For example, some of the conductive vias 108 depicted in FIGS. 1A-1B extend through the interface 133-3 with the substrate 102. One or more of the conductive vias 108 may also, or alternatively, extend through an interface with conductive bumps between dies of an IC structures 100-1-100-4.

The assemblies 150A and 150B may be formed with “via-last” or “via-mid” processes, respectively. With respect to via-last and via-mid processes, The terms “mid” and “last” may refer to the formation of the vias with respect to provision of the dies stacked and bonded with the bridge die, or may refer to where the vias land. For example, the assembly 150A may be an example resulting assembly of a via-last process, in which the dies of the IC structures 100-1-100-4 are stacked and bonded to the substrate 102 prior to forming the conductive vias 108. The assembly 150B may be an example resulting assembly of a via-mid process, where the conductive vias 108 are formed after providing at least one or more dies of the IC structures 100-1-100-4 over the bridge die 105, and where additional dies (e.g., additional dies of the final IC structures 100-1-100-4) may be provided after forming the conductive vias 108. Additionally, or alternatively, the assembly 150B may be considered an example resulting assembly of a via-mid process due to the conductive vias 108 extending into the bridge die (e.g., mid-way, or into a middle layer of the bridge die 105).

Various IC structures 100-1-100-4 may include different numbers of dies (e.g., the IC structures 100-1-100-4 may include one die or multiple stacked dies) and/or different types of dies (e.g., some of the IC structures 100-1-100-4 may include only memory dies, only logic dies, dies with both logic and memory, or a combination of types of dies). The various IC structures 100-1-100-4 may also have different heights or thicknesses relative to one another after bonding to the substrate 102 or to the bridge die 105. For example, the IC structure 100-1 has a height 152-1, the IC structure 100-2 has a height 152-2, the IC structure 100-3 has a height 152-3, and the IC structure 100-4 has a height 152-4 (where the heights of the IC structures are dimensions of the IC structures in a plane substantially orthogonal to the substrate 102, e.g., along the z-axis as shown in FIGS. 1A-1B). The heights of the IC structures may also be referred to as thicknesses of the IC structures.

As can be seen in FIGS. 1A-1B, the height 152-3 is greater than the heights 152-1, 152-2, and 152-4. Put another way, the height or thickness of some of the IC structures is smaller than the height or thickness of other IC structures. For example, the height 152-1 and the height 152-4 are smaller than the heights 152-2 and 152-3 and the height 152-2 is smaller than the height 152-3. Thus, there is a height or thickness difference amongst the IC structures 100-1, 100-2, and 100-4 and the IC structure 100-3. Specifically, there is a thickness difference 151-1 between the IC structures 100-1 and 100-3, a thickness difference 151-2 between the IC structures 100-2 and 100-3, and a thickness difference 151-4 between the IC structures 100-4 and 100-3. In some examples, an insulator material 115 may be provided over and between adjacent ones of the IC structures 100-1-100-4 to form a substantially flat or level surface over the plurality of IC structures 100-1-100-4. The IC structure 100-2 is an example of where an insulator material 115 is over the IC structure 100-2 in a plane with a taller IC structure (e.g., the insulator material 115 over the IC structure 100-2 is coplanar with the top layer or face of the IC structure 100-3). The insulator material 115 may be the same as, or different from, the insulator material 119 in the interface layer with the conductive bumps 114. In some examples, the insulator material 115 may include silicon oxide, silicon carbide, silicon nitride, an organic insulator material. In other examples, a dummy die 117 may be provided over one or more of the shorter IC structures to increase the height or thickness of the structure. The IC structure 100-1 is an example where a dummy die 117 is bonded over the IC structure 100-1, where the dummy die is in a plane with the taller IC structure 100-3 (e.g., the dummy die 117 is coplanar with the top layer or face of the IC structure 100-3). A dummy die may be a die that lacks devices (e.g., active devices). In other examples, both a dummy die (or multiple dummy dies) and an insulator material 115 may be used to level the height or thickness of different IC structures 100-1-100-4 over the substrate 102. The IC structure 100-4 is an example where both a dummy die 117 and the insulator material 115 is used to account for the height differences between IC structures over the substrate 102.

The location of the insulator material 115 and/or dummy dies 117 relative to the substrate 102 and the bridge die 105 is different in FIG. 1A and FIG. 1B. For example, in FIG. 1A, the insulator material 115 and/or dummy dies 117 are between the IC structures 100-1-100-4 and the bridge die 105. In one such example, the insulator material 115 and/or dummy dies 117 are provided over the IC structures 100-1-100-4 after bonding the IC structures 100-1-100-4 to the substrate 102 and before forming the conductive vias 108. Therefore, some of the conductive vias 108 in FIG. 1A extend through the insulator material 115. For example, a portion 155A of a conductive via 108 that extends through the IC structure 100-4 and through the insulator material 115 over the IC structure 100-4 is in a plane with a portion 157A of the insulator material 115 between the IC structure 100-4 and the bridge die 105 (e.g., between the IC structure 100-4 and the bridge die 105), where the plane is parallel to the bridge die 105. Also, as shown in the example in FIG. 1A, some of the conductive vias 108 extend through the dummy dies 117. For example, the conductive vias 108 through the IC structure 100-4 and 100-1 extend through a dummy die 117. For example, a portion 159A of a conductive via 108 that extends through the IC structure 100-1 and through the dummy die 117 over the IC structure 100-1 is in a plane with a portion 161A of the dummy die 117 between the IC structure 100-1 and the bridge die 105 (e.g., between the IC structure 100-1 and the bridge die 105), where the plane is parallel to the bridge die 105. In the example illustrated in FIG. 1A, the conductive vias 108 through the IC structures 100-1, 100-2, and 100-4 start at the insulator material 115 or dummy die 117, and therefore the widest portion of those vias may be in a plane with the insulator material 115 or a dummy die 117 (e.g., a width of a portion a via 108 in a plane with the insulator material 115 or a dummy die 117 through which the via 108 extends may be wider than a portion of the via closer to the substrate 102). In some examples where a dummy die 117 and/or an insulator material 115 is present over the IC structure, the dummy die 117 or insulator material 115 may be at, or in contact with, the interface 133-2 with the bridge die. In one such example, the dummy die 117 or insulator material 115 may be in direct contact (e.g., without an intervening layer) with the interface 133-2. In cases where an interface layer is substantially absent between the bridge die 105 and the assembly 160A, a dummy die 117 and/or the insulator material 115 may be in direct contact with the bridge die 105 at the interface 133-2.

In FIG. 1B, the insulator material 115 and/or dummy dies 117 are between the IC structures 100-1-100-4 and the substrate 102. In one such example, the insulator material 115 and/or dummy dies 117 are provided over the IC structures 100-1-100-4 after bonding the IC structures 100-1-100-4 to the bridge die 105 and before forming the conductive vias 108. Therefore, some of the conductive vias 108 in FIG. 1B also extend through the insulator material 115, like in FIG. 1A. For example, a portion 155B of a conductive via 108 that extends through the IC structure 100-4 and through the insulator material 115 over the IC structure 100-4 is in a plane with a portion 157B of the insulator material 115 between the IC structure 100-4 and the substrate 102 (e.g., between the IC structure 100-4 and the substrate 102), where the plane is parallel to the bridge die 105. Also, as shown in the example in FIG. 1B, some of the conductive vias 108 extend through the dummy dies 117. In the example illustrated in FIG. 1B, the conductive vias 108 through the IC structures 100-4 and 100-1 extend through a dummy die 117. For example, a portion 159B of a conductive via 108 that extends through the IC structure 100-1 and through the dummy die 117 over the IC structure 100-1 is in a plane with a portion 161B of the dummy die 117 between the IC structure 100-1 and the substrate 102 (e.g., between the IC structure 100-1 and the substrate 102), where the plane is parallel to the bridge die 105. In the example illustrated in FIG. 1B, the conductive vias 108 through the IC structures 100-1, 100-2, and 100-4 start at or proximate to the insulator material 115 or dummy die 117, and therefore the widest portion of those vias may be in a plane with the insulator material 115 or a dummy die 117 (e.g., a width of a portion via 108 of FIG. 1B in a plane with the insulator material 115 or a dummy die 117 through which the via 108 extends may be wider than a portion of the via closest to the bridge die 105). In some examples where a dummy die 117 and/or an insulator material 115 is present over the IC structure, the dummy die 117 or insulator material 115 may be at, or in contact with, the interface 133-3 with the substrate 102. In one such example, the dummy die 117 or insulator material 115 may be in direct contact (e.g., without an intervening layer) with the interface 133-3. In cases where an interface layer is substantially absent between the substrate 102 and the assembly 160B, a dummy die 117 and/or the insulator material 115 may be in direct contact with the substrate 102 at the interface 133-2.

Referring again to FIG. 1A, the conductive vias 108 are formed from the side 130A of the assembly 160A opposite the substrate 102, and thus taper towards the substrate 102. Various ones of the conductive vias 108 land or terminate on conductive elements in the substrate 102 or at an interface between the IC structures 100-1-100-4 and the substrate 102. In the example illustrated in FIG. 1A, the plurality of conductive vias 108 pass entirely through the IC structures 100-1-100-4 (e.g., entirely through the die or die stacks of the IC structures 100-1-100-4) so that portions of the conductive vias 108 are coplanar with top layers of the IC structures 100-1-100-4 through which they extend, and may also be coplanar with bottom layers of the IC structures 100-1-100-4.

Referring to FIG. 1B, the conductive vias 108 are formed from the side 131B of the assembly 160B opposite the bridge die 105, and thus taper towards the bridge die 105. Various ones of the conductive vias 108 land or terminate on conductive elements in the bridge die 105 or at an interface between the IC structures 100-1-100-4 and the bridge die 105. In the example illustrated in FIG. 1B, the plurality of conductive vias 108 pass entirely through the IC structures 100-1-100-4 (e.g., entirely through the die or die stacks of the IC structures 100-1-100-4) so that portions of the conductive vias 108 are coplanar with top layers of the IC structures 100-1-100-4 through which they extend, and may also be coplanar with bottom layers of the IC structures 100-1-100-4.

Thus, conductive vias 108 may be formed during assembly to enable the formation of vias that extend through inter-die interfaces and in some cases, into a bridge die (such as shown in FIG. 1B). Conductive vias in accordance with examples described herein may enable improved system performance (e.g., by enabling high frequency signaling between adjacent IC structures on a circuit board). Conductive vias in accordance with examples described herein may also enable improved thermal management. Unlike conventional IC structures in which conductive vias terminate at interfaces with conductive bumps, resulting in thermal boundaries that limit heat dissipation, a bridge die and through-assembly conductive vias can enable a thermal channel between multiple dies without thermal boundaries for improved thermal management. Finally, conductive vias formed during or after assembly of various components can enable flexibility in terms of multi-fabrication processing. For example, conductive vias may be formed at different stages of fabrication and assembly to enable the use of packages and dies from multiple fabs.

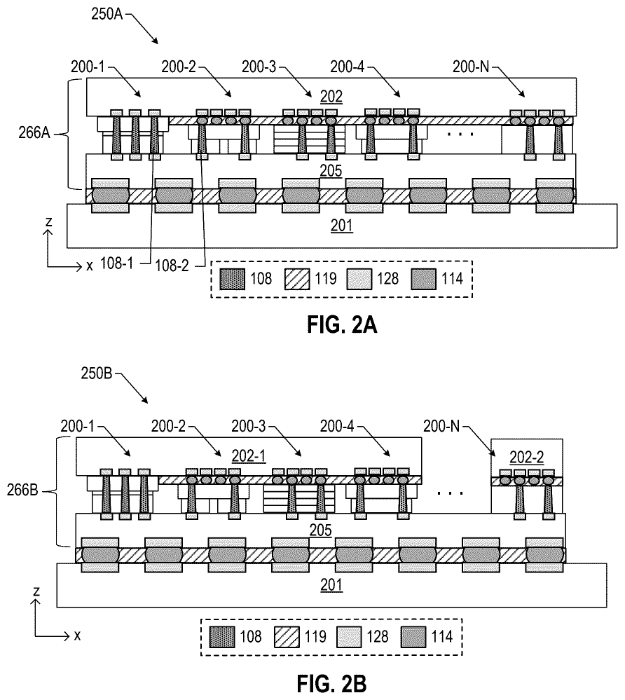

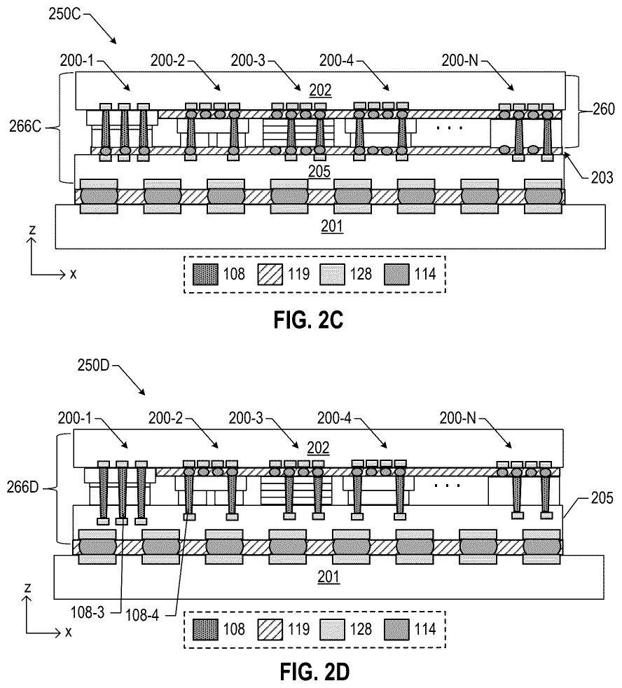

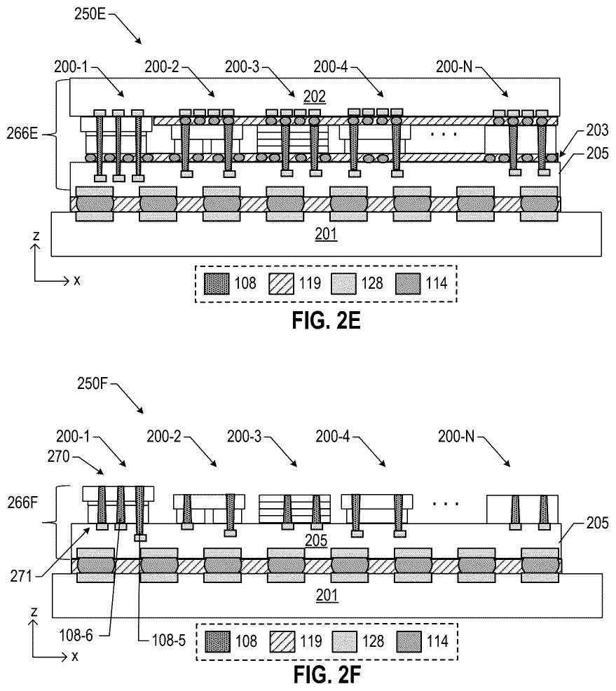

FIGS. 2A-2F illustrate cross-sectional views of various assemblies 250A-250F that include a bride die and through-assembly vias. FIGS. 2A-2C illustrate examples of assemblies 250A-250C that include conductive vias that are formed after bonding the IC structures with the substrate 202, and which taper in a direction from the bridge die 205 towards the substrate 202. FIGS. 2D-2E illustrate examples of assemblies 250D-250E that include conductive vias that are formed after bonding the IC structures with the bridge die 205, and which taper in a direction from the substrate 202 towards the bridge die 205. FIG. 2F illustrates an example of an assembly 250F with both conductive vias formed after bonding the IC structures with the substrate 202, and conductive vias formed after bonding the IC structures with the bridge die 205.

The assemblies 250A-250F of FIGS. 2A-2F each include a subassembly (e.g., the assemblies 266A-266F) that includes N IC structures 200-1-200-N(of which IC structures 200-1, 200-2, 200-3, 200-4, and 200-N are shown) bonded with a bridge die 205, where N is a positive integer greater than one. The subassemblies 266A-266F of FIGS. 2A-2F are attached to a circuit board 201 via a plurality of conductive bumps 114. The subassemblies 266A-266E of FIGS. 2A-2E further include a substrate 202, where the IC structures 200-1-200-N are between the substrate 202 and the bridge die 205. The IC structures 200-1-200-N may be examples of the IC structures 100 discussed above with respect to FIGS. 1A-1D, and may include one or more dies. For example, the IC structure 200-N includes a single die. The IC structure 200-4 includes a die stack of two dies stacked over one another. The IC structure 200-3 includes a die stack of four dies stacked over one another. The IC structure 200-2 includes two coplanar dies stacked over another die (e.g., over a base die). The IC structure 200-1 includes two stacked dies bonded together via a thinner interconnect die. Different and/or additional IC structures are possible, as mentioned above. The circuit board 201 may be an example of the circuit board 101, the substrate 202 may be an example of the substrate 102, and the bridge die 205 may be an example of the bridge die 105, discussed above with respect to FIGS. 1A-1D. Although not shown in FIGS. 2A-2B, an insulator material may be present between and around the IC structures 200-1-200-N, such as the insulator material 115, discussed above with respect to FIGS. 1A-1B.

Turning first to FIG. 2A, the assembly 250A includes a circuit board 201 and an assembly 266A over and attached to the circuit board 201. The assembly 266A includes an interconnect structure (e.g., the bridge die 205) over the circuit board, and a plurality of IC structures 200-1-200-N over and bonded with the bridge die 205. The plurality of IC structures 200-1-200-N includes a first IC structure (e.g., the IC structure 200-1) in a first plane substantially parallel with the circuit board 201, and a second IC structure (e.g., the IC structure 200-2) in the first plane. In the example illustrated in FIG. 2A, the IC structure 200-1 is hybrid bonded to the substrate 202, and the IC structures 200-2, 200-3, 200-4, and 200-N are bonded with the substrate 202 via conductive bumps 114. The IC structures 200-1-200-N are hybrid bonded to the bridge die 205. The assembly 250A further includes a first conductive via 108-1 through the first IC structure 200-1 and a second conductive via 108-2 through the second IC structure 200-2, where the first conductive via 108-1 and the second conductive via 108-2 taper in a direction away from the interconnect structure (e.g., away from the bridge die 205). A conductive interconnect in the bridge die 205 or substrate 202 may be coupled with the first conductive via 108-1 and the second conductive via 108-2.

FIG. 2B illustrates an assembly 250B that is similar to the assembly 250A, with conductive vias 108 through the IC structures 200-1-200-N that taper in a direction from the bridge die 205 towards the substrate 202. The assembly 250B differs from the assembly 250A in that the IC structures 200-1, 200-2, 200-3, and 200-4 are between the bridge die 205 and a first substrate 202-1, and the IC structure 200-N is between the bridge die 205 and a second substrate 202-2 that is a separate structure (e.g., a separate die) from the substrate 202-1. In one such example, the IC structure 200-N may be bonded with the substrate 202-2 independently (e.g., with a separate independent process) from bonding the IC structures 200-1, 200-2, 200-3, and 200-4 with the substrate 202-1. Similarly, the conductive vias in 108 through the IC structure 200-N may be formed independently from the formation of the conductive vias 108 in the IC structures 200-1, 200-2, 200-3, and 200-4. In one such example, the separate substrates 202-1 and 202-2 may enable some processes (e.g., bonding the IC structures with the substrates and/or the formation of conductive vias through the IC structures) to be performed in different fabs (e.g., split fabrication). The IC structures 200-1-200-4 and 200-N bonded with the substrates 202-1 and 202-2, respectively, may then be bonded with the bridge die 205 to form an assembly 266B, which may be attached to the circuit board 201.

FIG. 2C illustrates another assembly 250C that is similar to the assembly 250A, with conductive vias 108 through the IC structures 200-1-200-N that taper in a direction from the bridge die 205 towards the substrate 202. The assembly 250C differs from the assembly 250A in that the interface 203 between the IC structures 200-1-200-N and the bridge die 205 (e.g., between an assembly 260 that includes the IC structures 200-1-200-N and the substrate 202) includes conductive bumps 114 instead of a hybrid bonding interface, as shown in FIG. 2A. In the example illustrated in FIG. 2C, some of the conductive vias 108 couple with conductive bumps 114 at the interface 203 between the assembly 260 and the bridge die 205, such as the conductive vias 108 through the IC structures 200-1, 200-2, 200-3, and 200-4. Also as shown in the example illustrated in FIG. 2C, some of the conductive vias 108 extend through the interface 203 and couple directly with conductive pads 128 of the bridge die 205, such as the conductive vias 108 through the IC structure 200-N of FIG. 2C.

FIG. 2D illustrates an assembly 250D, which includes a circuit board 201 and an assembly 266D over and attached to the circuit board 201. Similar to the assemblies shown in FIGS. 2A-2C, the assembly 266D includes an interconnect structure (e.g., a bridge die 205) over the circuit board 201, and a plurality of IC structures 200-1-200-N over and bonded with the bridge die 205, where the IC structures 200-1-200-N include a first IC structure 200-1 including one or more first dies, and a second IC structure 200-2 including one or more second dies. The assembly 250D includes a first conductive via 108-3 through the one or more first dies of the first IC structure 100-1 and at least partially through the bridge die 205, and a second conductive via 100-4 through the one or more second dies of the second IC structure 100-2 and at least partially through the interconnect structure 105. For example, as can be seen in FIG. 2D, a portion of the first conductive via 100-3 and a portion of the second conductive via 100-4 are coplanar with a layer of the interconnect structure (e.g., coplanar with an interconnect layer of the bridge die 205). A conductive interconnect in the bridge die 205 may be coupled with the first conductive via 109-3 and the second conductive via 108-4. In the example illustrated in FIG. 2D, the conductive vias 108 taper in a direction from the substrate 202 towards the bridge die 205.

FIG. 2E illustrates an assembly 250E that is similar to the assembly 250D, with conductive vias 108 that extend through the IC structures 200-1-200-N and into the bridge die 205. The assembly 250E differs from the assembly 250D of FIG. 2D in that the IC structures 200-1-200-N are bonded with the bridge die 205 via conductive bumps 114. Thus, the conductive vias 108 through the assembly 266E extend through an interface 203 that includes conductive bumps 114 and an insulator material 119 coplanar with the conductive bumps 114.

FIG. 2F illustrates an assembly 250F that includes some conductive vias that extend into the bridge die 205 and taper towards the bridge die, and some conductive vias that taper away from the bridge die 205 (and which coupled with the bridge die 205, but do not extend into the bridge die 205). For example, the assembly 266F includes the conductive via 108-5 that extends through the IC structure 200-1 and into the bridge die 205, and which tapers in a direction towards the bridge die 205. The assembly 266F also includes the conductive via 108-6 that extends through the IC structure 200-1 and is coupled with a conductive element of the bridge die 205 (e.g., with a conductive pad 128 of the bridge die), and which tapers away from the bridge die 205. In one such example, one or more of the IC structures 200-1-200-N are first bonded with a substrate (not shown in FIG. 2F), and conductive vias may be formed through one or more of the IC structures 200-1-200-N. For example, the side or face 270 of the IC structure 200-1 may be bonded with a substrate, such as the substrate 202 of FIGS. 2A-2E. The conductive via 108-6 may then be formed through the IC structure 200-1 from the opposite side or face 271. A subassembly of the substrate and one or more of the IC structures 200-1-200-N may then be bonded with the bridge die 205. For example, the side or face 271 may be bonded with the bridge die 205, and the substrate may be removed to reveal the opposite side or face 270. The conductive via 108-5 may then be formed from the side or face 270, where the conductive via 108-5 may extend through the IC structure 200-1, through an interface between the IC structure 200-1 and the bridge die 205, and into the bridge die 205. Thus, in one such example, the conductive vias 108-5 and 108-6 were formed from opposite sides of the IC structures, and therefore taper in opposite directions (e.g., the wider end of the conductive via 108-6 is near the bridge die 205, and the narrower end of the conductive via 108-5 is near or in the bridge die 205). Although FIG. 2F depicts an assembly 250F without a top substrate, in other examples, a substrate 202 may be provided over the assembly 266F.

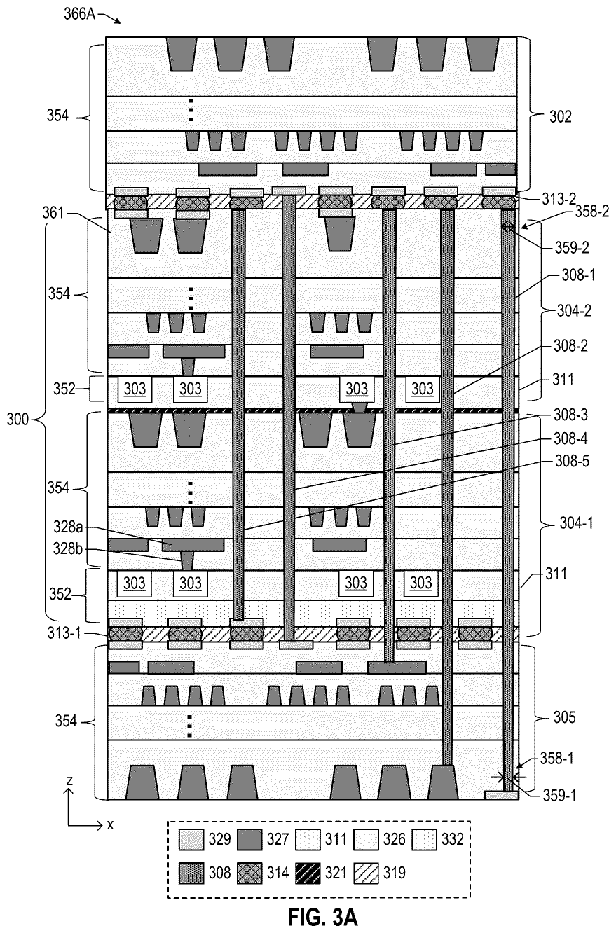

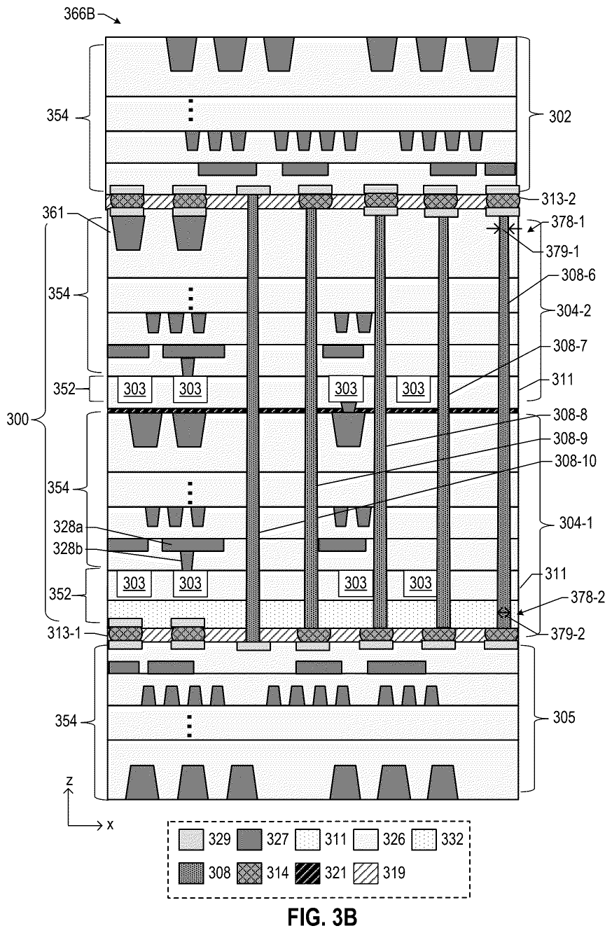

FIGS. 3A-3B illustrate cross-sectional views of an assemblies 366A, 366B including a bridge die and through-assembly conductive vias. In the examples illustrated in FIGS. 3A-3B, the assemblies 366A, 366B include an IC structure 300 that includes two stacked dies 304-1, 304-2 between a bridge die 305 and a substrate 302. The first die 304-1 and the second die 304-2 each include FEOL layers 352 and BEOL layers 354. The FEOL layers 352 include a device region 311, and may also include a substrate 332 over which the device region 311 is disposed. The device region 311 includes devices (of which devices 303 are shown). The substrate 332 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device 303 is an example of a frontend device. The device 303 may be considered a “frontend device” due to its location in a FEOL layer. According to examples, the device 303 may include a transistor of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region 311 may be electrically isolated from one another by any suitable insulator material 326.

The BEOL layers 354 may include a plurality of conductive interconnects 327 electrically coupled to (e.g., in electrically conductive contact with at least portions of) one or more of the plurality of devices of the FEOL layers 352. Various BEOL interconnect layers 354 may be/include one or more metal layers of a metallization stack of the dies 304-1 or 304-2. In the example illustrated in FIGS. 3A-3B, the interconnect layers 354 are disposed over a front side of the device region, and therefore may be considered frontside interconnect layers. In other examples, one or both of the dies 304-1 and 304-2 may include both frontside and backside interconnect layers. The die 304-1 may also include one or more backend devices (not shown). A device may be considered a “backend device” due to its location in a BEOL layer. A backend device may be present in lower or higher up interconnect layers in the metallization stack. In one example, a backend device may include a transistor of any architecture, such as any non-planar or planar architecture, or other device.

Various metal layers of the BEOL interconnect layers 354 may be used to interconnect the various inputs and outputs of the devices (e.g., logic devices) in the FEOL layers 352. In one example, each of the BEOL interconnect layers 354 may include vias and lines/trenches. For example, the BEOL interconnect layers 354 include via portions 328b and line or trench/interconnect portions 328a. The trench portion 328a of a metal layer is configured for transferring signals and power along electrically conductive (e.g., metal) lines (also sometimes referred to as “trenches”) extending in the x-y plane (e.g., in the x or y directions), while the via portion 328b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 354 may include only certain patterns of conductive metals, e.g., copper (Cu), aluminum (AI), tungsten (W), or cobalt (Co), or metal alloys, or more generally, patterns of an electrically conductive material, formed in an insulating medium such as an ILD material 326. The insulating medium may include any suitable ILD materials such as silicon oxide, carbon-doped silicon oxide, silicon carbide, silicon nitride, aluminum oxide, and/or silicon oxynitride. In some embodiments, the dielectric material 326 disposed between the interconnect structures in different ones of the interconnect layers and disposed in the device region 311 may have different compositions; in other embodiments, the composition of the dielectric material 326 between different interconnect layers and/or in the device region 311 may be the same. The examples illustrated in FIGS. 3A-3B depict three interconnect layers in the BEOL layers 354; however, fewer or more interconnect layers may be present.

As mentioned briefly above, the IC structure 300 includes two dies stacked over one another (e.g., a first die 304-1 and a second die 304-2). The second die 304-2 is stacked over and bonded with the first die 304-1 via an interface 321. Although FIGS. 3A-3B depict the second die 304-2 as having the same width as the first die 304-1 (e.g., the same dimension along the x-axis as shown in FIGS. 3A-3B), the second die 304-2 may have a width that is different from the first die 304-1. In some examples, one or multiple smaller coplanar dies may be bonded over the first die 304-1. The interface 321 between the first die 304-1 and the second die 304-2 may include, for example, a hybrid bonding interface, such as discussed above. In other examples, the interface 321 may include conductive bumps.

The die stack that includes the dies 304-1 and 304-2 is over and bonded with the bridge die 305 via an interface 313-1, and a substrate 302 is over and bonded with the die stack via an interface 313-2. The bridge die 305 may be an example of the bridge die 105, and the substrate 302 may be an example of the substrate 102, discussed above. The substrate 302 and/or the bridge die 305 may include a plurality of interconnect layers 354 that include conductive interconnects 327. The interface 313-1 includes conductive bumps 314 between the IC structure 300 and the bridge die 305 (e.g., between the die 304-1 and the bridge die 305). The interface 313-2 includes conductive bumps 314 between the IC structure 300 and the substrate 302 (e.g., between the die 304-2 and the substrate 302). The interfaces 313-1, 313-2 include an insulator material 319 in a plane with the conductive bumps 314 (e.g., in a plane substantially parallel with the substrate 302 and bridge die 305 and substantially parallel with the x-y plane as shown in FIGS. 3A, 3B, where the y-axis is going into and coming out of the page). The interfaces 313-1, 313-2 may also be referred to as interface layers, which include conductive bumps 314. The conductive bumps 314 may be an example of the conductive bumps 114 discussed above. In the example illustrated in FIGS. 3A-3B, a conductive bump is between and coupled with conductive elements in the two bonded IC structures. For example, the conductive bumps shown in FIGS. 3A-3B are either between two conductive pads 329, or between a conductive pad 329 and a conductive via 308. Although only a single die stack (e.g., the IC structure 300) is shown between the bridge die 305 and substrate 302, more than one IC structure may be between and bonded with the bridge die 305 and the substrate 302, such as shown in FIG. 1A.

The assemblies 366A, 366B also include a plurality of conductive vias 308 that extend through the IC structure 300 (e.g., completely through the dies 304-1, 304-2) and couple with a conductive element of the substrate 302 and/or a conductive element of the bridge die 305. The conductive vias 308 may be formed in an assembly that includes the IC structure 300 and the bridge die 305 or the substrate 302, and thus the conductive vias 308 may be considered to be through-assembly conductive vias. In the example shown in FIGS. 3A-3B, the conductive vias 308 extend entirely through the IC structure 300, so that portions of the conductive vias 308 are coplanar with the bottom and top layers or faces of the IC structure 300. For example, the conductive vias 308 are in a same plane as a top metal layer of the die 304-2. For example, the end 358-2 of the conductive via 308-1 is coplanar with the metal layer 361 and with conductive interconnects of the metal layer 361. In the example illustrated in FIGS. 3A-3B, the conductive vias 308 also extend through both the metal layers (e.g., metallization stacks) and the device regions 311 of the dies 304-1 and 304-2, as well as through the interface 321 between the dies 304-1, 304-2 of the IC structure 300. In an example in which one or both of the dies 304-1, 304-2 include both frontside and backside metal layers, one or more of the conductive vias 308 may extend through both the frontside and backside metal layers of a die.

The conductive vias illustrated in FIGS. 3A-3B start and end (e.g., land or terminate) at different points in the assemblies 366A and 366B, where the “start” and “end” of a conductive via may refer to the two ends of a conductive via and may be interchangeable. Referring to FIG. 3A, the conductive vias 308-1, 308-2, 308-3, and 308-5 start at a face or side of the IC structure 300 at the interface 313-2, and the via 308-4 starts at the interface 313-2 between the IC structure 300 and the substrate 302. The conductive vias 308 also land or terminate at different points in the IC structure 300 or the bridge die 305. For example, some of the conductive vias 308 shown in FIG. 3A (e.g., the conductive vias 308-1, 308-2, 308-3, and 308-4) extend through the interface 313-1 (e.g., through the insulator material 319 that is coplanar with the conductive bumps 314). In some examples, one or more of the conductive vias 308 may extend between adjacent conductive bumps 314 so that a portion of the conductive vias is between the adjacent conductive bumps 314 and in a same plane with the conductive bumps 314. In other examples, one or more conductive vias 308 may extend through the interface 313-1 at the periphery of the interface 313-1, so that the conductive via is not between adjacent bumps. In one such example, the conductive via may still be adjacent to or neighboring at least one conductive bump 314. Some of the conductive vias of FIG. 3A extend into the bridge die, so that a portion of the conductive vias are in a same layer or plane with an interconnect layer of the bridge die 305. For example, the conductive vias 308-1, 308-2, and 308-3 have portions that are coplanar with interconnect layers of the bridge die. Additionally, the conductive vias 308-1 and 308-2 extend through one or more metal layers of the bridge die 305.

In the example illustrated in FIG. 3A, the conductive vias 308 that extend through the interface 313-1 terminate or land on a conductive element in the bridge die 305. For example, the conductive via 308-1 is coupled with a bonding pad 329. The conductive vias 308-2, 308-3 are coupled with conductive lines (e.g., trench portions 328a) in different metal layers. The conductive via 308-4 is coupled with a conductive pad at the interface 313-1 (e.g., a conductive pad that is coplanar with a face of the bridge die 305 that is bonded with the IC structure 300, and coplanar with the other conductive pads of the bridge die 305 that are coupled with the conductive bumps 314). The conductive via 308-5 does not extend through the interface 313-1, but is coupled with a conductive element of the IC structure 300. As shown in FIG. 3A, the conductive via 308-5 is coupled with a conductive pad 329; however, in other examples, the conductive via 308-5 may be coupled directly with the conductive bump 314 or another conductive element of the IC structure 300.

Referring to FIG. 3B, the conductive vias 308-6, 308-7, 308-8, and 308-9 start at a face or side of the IC structure 300 at the interface 313-1, and the via 308-10 starts at the interface 313-1 between the IC structure 300 and the bridge die 305. Similarly, the conductive vias 308-6, 308-7, 308-8, 308-9 end at a face or side of the IC structure 300 at the interface 313-2, and the via 308-10 ends at the interface 313-2 between the IC structure 300 and the substrate. Thus, the conductive vias 308-6, 308-7, 308-8, 308-9 and 308-10 extend through the IC structure 300, and the ends of the conductive vias 308-6, 308-7, 308-8, 308-9 and 308-10 are coplanar with the sides or faces of the IC structure 300 bonded with the bridge die 305 and the substrate 302, or coplanar with the interfaces 313-1, 313-2 between the IC structure 300 and the bridge die 305 or substrate 302.

Referring again to the example illustrated in FIG. 3A, the conductive vias 308 may be formed in the assembly 366A from a top face or side of the IC structure 300 after bonding the IC structure 300 with the bridge die 305 (e.g., the conductive vias 308 may be formed from the side or face of the IC structure 300 opposite the side or face that is bonded with the bridge die 305). Therefore, in the example illustrated in FIG. 3A, the conductive vias 308 taper towards the bridge die 305. For example, the conductive via 308-1 has a first end 358-1 coupled with a conductive element (e.g., a conductive pad 329), and a second end 358-2 that is opposite the first end 358-1. The first end 358-1 has a first width 359-1 and the second end 358-2 has a second width 359-2 that is larger than the first width 359-1 (where the first width 359-1 and the second width 359-2 are dimensions of the conductive via 308-1 in a plane substantially parallel to the substrate 302 and bridge die 305). In other words, the first end 358-1 of the conductive via 308-1 that is coupled with the conductive element of bridge die 305 is narrower than the second end 358-2 of the conductive via 308-1 that is opposite from the first end 358-1. After attaching the assembly 366A to a circuit board (e.g., via the side of the assembly 366A with the bridge die 305), the first end 358-1 (e.g., the narrower end) of the conductive via 308-1 is closer to the circuit board than the second end 358-2.

In the example illustrated in FIG. 3B, the conductive vias 308 may be formed in the assembly 366B from a top face or side of the IC structure 300 after bonding the IC structure 300 with the substrate 302 (e.g., the conductive vias 308 may be formed from the side or face of the IC structure 300 opposite the side or face that is bonded with the substrate 302). Therefore, in the example illustrated in FIG. 3B, the conductive vias 308 taper away from the bridge die 305 and towards the substrate. For example, the conductive via 308-6 has a first end 378-1 coupled with a conductive element (e.g., a conductive pad 329), and a second end 378-2 that is opposite the first end 378-1. The second end 378-2 may be coupled with another conductive element (e.g., the conductive bump in the interface 313-1). The first end 378-1 has a first width 379-1 and the second end 378-2 has a second width 379-2 that is larger than the first width 379-1 (where the first width 379-1 and the second width 379-2 are dimensions of the conductive via 308-6 in a plane substantially parallel to the substrate 302 and bridge die 305). In other words, the first end 378-1 of the conductive via 308-6 that is proximate to the substrate 302 is narrower than the second end 378-2 of the conductive via 308-6 coupled with a conductive element of the bridge die 305, where the second end 378-2 is opposite from the first end 378-1. After attaching the assembly 366B to a circuit board (e.g., the side of the assembly 366B with the bridge die 305), the second end 378-2 (e.g., the wider end) of the conductive via 308-6 is closer to the circuit board than the first end 378-1.

Thus, the assemblies 366A, 366B each include an IC structure with one or more dies between a substrate 302 and a bridge die 305 and conductive vias through the assemblies 366A, 366B. Although FIGS. 3A and 3B depict only two dies 304-1 and 304-2 between and bonded with the substrate 302 and bridge die 305, in other examples, the IC structure 300 may include fewer dies (i.e., a single die) or more than two dies (e.g., three dies, four dies, etc.) between and bonded with the substrate 302 and bridge die 305. In some examples, the conductive interconnects of the substrate 302 and/or bridge die 305 couple with the conductive vias 308 though the dies 304-1, 304-2 and/or with conductive vias through other dies or die stacks bonded with bridge die 305 or the substrate 302.

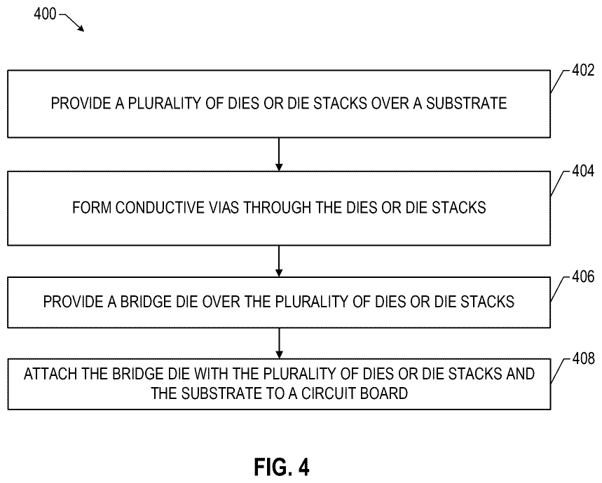

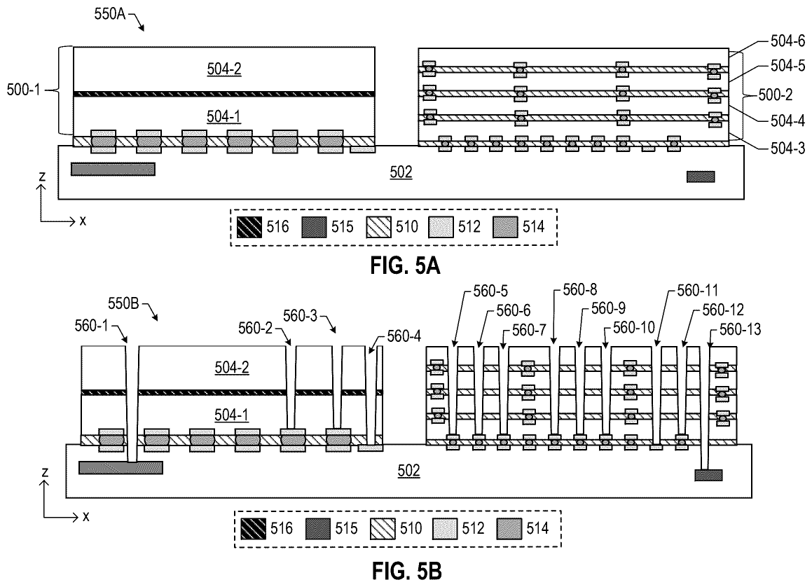

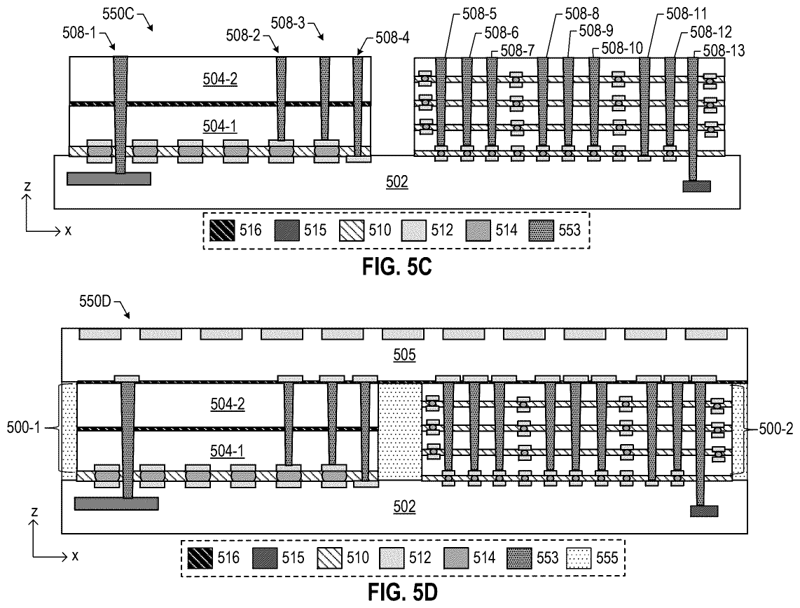

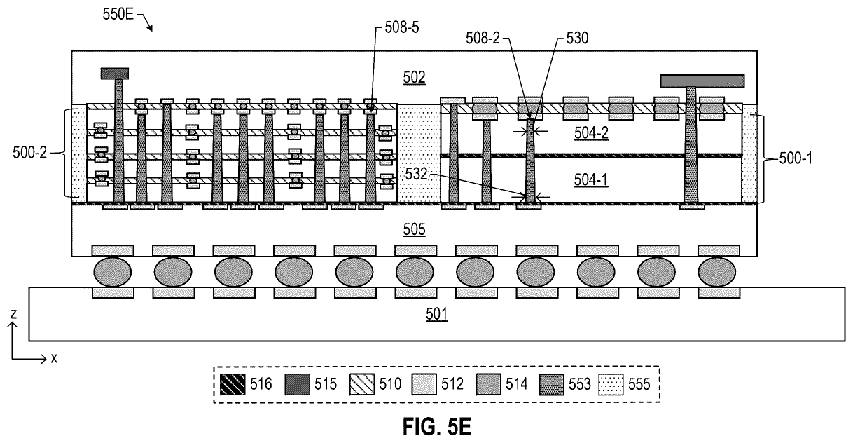

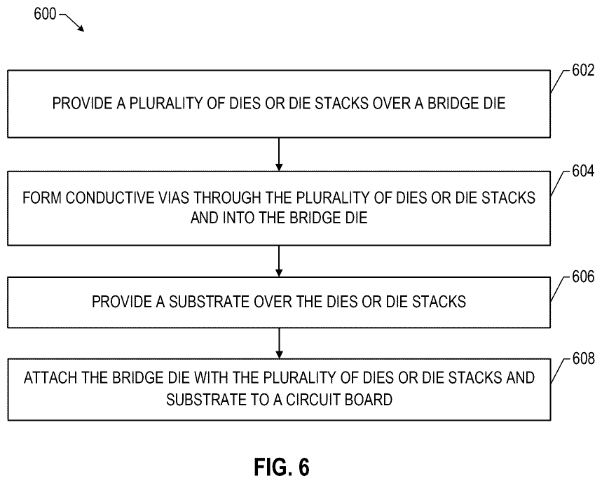

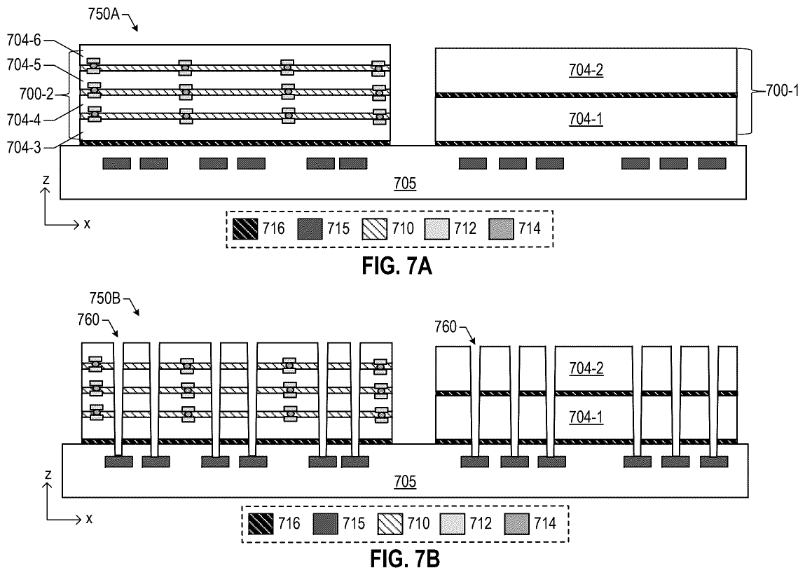

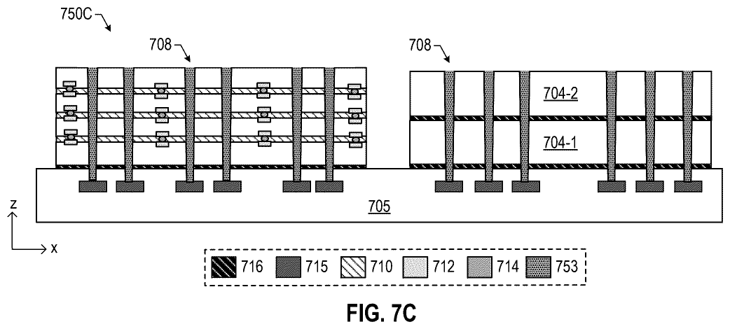

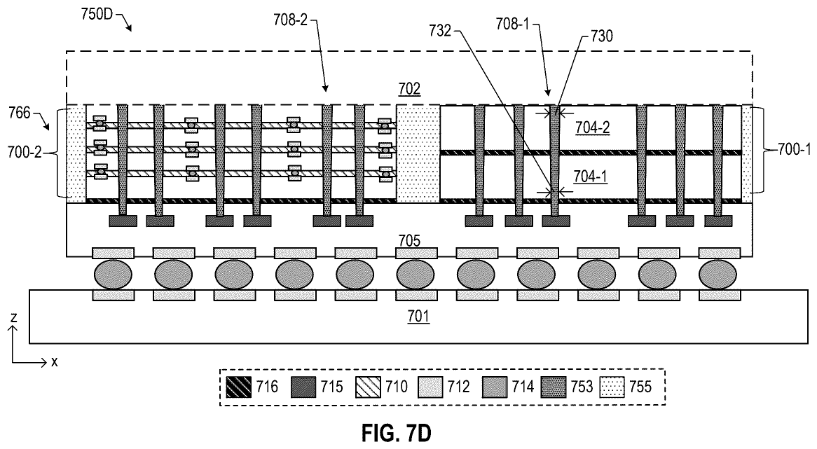

FIGS. 4 and 6 are flow diagrams of example methods 400 and 600 for fabricating a microelectronic assembly with a bridge die and through-assembly conductive vias. FIGS. 5A-5E provide different views at various stages in the fabrication of an example assembly according to the method of FIG. 4, in accordance with some embodiments. FIGS. 7A-7D provide different views at various stages in the fabrication of an example assembly according to the method of FIG. 6, in accordance with some embodiments. Although the operations of the methods of FIGS. 4 and 6 are illustrated once each and in a particular order, the operations may be performed in any suitable order and repeated as desired. For example, one or more operations may be performed in parallel to fabricate multiple microelectronic assemblies with a bridge die and through-assembly conductive vias substantially simultaneously. In another example, the operations may be performed in a different order to reflect the structure of a microelectronic assembly in which a bridge die and through-assembly conductive vias will be implemented.

In addition, the example fabricating methods of FIGS. 4 and 6 may include other operations not specifically shown in FIGS. 4 and 6, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods of FIGS. 4 and 6 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of providing a plurality of dies or die stacks over a substrate. The assembly 550A of FIG. 5A is an example resulting assembly of the process 402. The assembly 550A includes a substrate 502 and two IC structures 500-1, 500-2 over and bonded with the substrate 502. The substrate 502 may be an example of the substrate 102, discussed above, and may include conductive elements, such as the conductive pads 512 and/or conductive interconnects 515, such as shown in FIG. 5A. The IC structures 500-1 and 500-2 may be examples of the IC structure 100, discussed above. In the example illustrated in FIG. 5A, the IC structure 500-1 is a die stack that includes two dies 504-1, 504-2 bonded together with a hybrid bonding technique, as shown with the interface 516. In the example illustrated in FIG. 5A, the IC structure 500-2 is a die stack that includes four dies 504-3, 504-4, 504-5, and 504-6 bonded together with conductive bumps 514.

In the example shown in FIG. 5A, the IC structures 500-1, 500-2 are bonded with the substrate 502 with a plurality of conductive bumps 514, which are between conductive pads of the IC structures 500-1, 500-2 and the substrate 502. An insulator material 510 may also be present between the IC structures 500-1, 500-2 and the substrate 502 in a plane with the plurality of conductive bumps 514. Thus, multiple IC structures 500-1, 500-2, which may be from different fabs, may be bonded with the substrate 502 to form an assembly 550A. In other examples, different bonding techniques may be used to bond the IC structures 500-1, 500-2 with the substrate 502 and/or to bond together adjacent dies of the IC structures 500-1, 500-2.

The method 400 continues with a process 404 of forming conductive vias through the dies or die stacks. Forming conductive vias through the dies or die stacks may involve first forming openings through the dies or die stacks, and filling the openings with a conductive material. The assembly 550B of FIG. 5B is an example resulting assembly of the process of forming openings through the dies or die stacks. The assembly 550B includes openings 560-1, 560-2, 560-3, and 560-4 through the IC structure 500-1, and openings 560-5, 560-6, 560-7, 560-8, 560-9, 560-10, 560-11, 560-12, and 560-13 through the IC structure 500-2. Forming the openings 560-1-560-13 may involve any suitable masking and etching techniques that enable etching through multiple layers of different materials. For example, the process of forming the openings 560-1-560-13 involves etching through multiple layers of semiconductor material, insulator material, and may also involve etching through conductive material. Any suitable etching technique, e.g., a dry etch, such as e.g., radio frequency (RF) reactive ion etch (RIE) or inductively coupled plasma (ICP) RIE may be used to form the openings 560-1-560-13. Some of the openings 560-1-560-13 extend through interfaces with conductive bumps. For example, the openings 560-1, 560-4, and 560-13 extend through the interface with conductive bumps 514 between the IC structures 500-1, 500-2 and the substrate 502. The openings 560-5-560-13 extend through inter-die interfaces with conductive bumps 514 between adjacent dies of the die stack of the IC structure 500-2.

The assembly 550C of FIG. 5C is an example resulting assembly of the process of filling the openings 560-1-560-13. The assembly 550C includes conductive vias 508-1, 508-2, 508-3, and 508-4 through the IC structure 500-1, and conductive vias 508-5, 508-6, 508-7, 508-8, 508-9, 508-10, 508-11, 508-12, and 508-13 through the IC structure 500-2 formed by filling the openings 560-1-560-13 with a conductive material 553. The electrically conductive material 553 may include any suitable electrically conductive material, such as any of those described above, and may be deposited using a technique such as atomic layer deposition (ALD), chemical vapor deposition (CVD), plasma enhanced CVD (PECVD), or/and physical vapor deposition (PVD) processes such as sputter. Although not shown in FIG. 5C, a liner may be provided in the openings 560-1-560-13 prior to filling the openings 560-1-560-13 with the conductive material 553. One or more of the conductive vias 508-1-508-13 may land on, and be coupled with, conductive pads 512 of the IC structures 500-1, 500-2, conductive pads 512 of the substrate 502, and/or conductive interconnects of the substrate 502. For example, in FIG. 5C, the conductive vias 508-1 and 508-13 are coupled with conductive interconnects in the substrate 502. Also as shown in FIG. 5C, the conductive vias 508-2-, 508-3, 508-5, 508-6, 508-7, 508-8, 508-9, 508-10, and 508-12 are coupled with conductive pads of the IC structure through which they extend. The conductive vias 508-4 and 508-11 are coupled with conductive pads in the substrate 502.

The method 400 continues with a process 406 of providing a bridge die over the plurality of dies or die stacks. The assembly 550D of FIG. 5D is an example resulting assembly of the process 406. The assembly 550D includes a bridge die 505 over and bonded with the IC structures 500-1 and 500-2. The bridge die 505 may be an example of the bridge die 105, discussed above. The bridge die 505 may include conductive interconnects (not shown in FIG. 5D), and conductive pads 512 on both sides to enable bonding and connection between conductive features in the bridge die 505, the IC structures 500-1, 500-2, and a circuit board. In the example illustrated in FIG. 5D, the bridge die 505 is bonded with the IC structures 500-1 and 500-2 via a hybrid bonding interface 516. In other examples, the bridge die 505 may be bonded with the IC structures 500-1, 500-2 via other bonding techniques. In some examples, an insulator material may be provided between adjacent IC structures and/or over IC structures. For example, the assembly 550D in FIG. 5D includes an insulator material 555 between IC structures 500-1 and 500-2.

The method 400 continues with a process 408 of attaching the bridge die with the plurality of dies or die stacks to a circuit board. The assembly 550E of FIG. 5E is an example resulting assembly of the process 408. The assembly 550E includes a circuit board 501 over which a preliminary assembly (e.g., the assembly 550D including the IC structures 500-1, 500-2 between and bonded with the substrate 502 and the bridge die 505) is bonded. The circuit board 501 may be an example of the circuit board 101, discussed above. As can be seen in FIG. 5E, the assembly 550D was first flipped over prior to bonding to the circuit board 501 to enable the exposed tops of the conductive vias 560-1-560-13 to be bonded with conductive elements of the circuit board 501. Therefore, the conductive vias 560-1-560-13 taper away from the circuit board 501 and towards the substrate 502.

FIG. 6 is a flow chart of another method 600 of fabricating an assembly with a bridge die and through-assembly conductive vias. The method 600 begins with a process 602 of providing a plurality of dies or die stacks over a bridge die. The assembly 750A of FIG. 7A is an example resulting assembly of the process 602. The assembly 750A includes two IC structures 700-1, 700-2 over and bonded with a bridge die 705. The bridge die 705 may be an example of the bridge die 105, discussed above. The bridge die 705 may include conductive elements 715, such as conductive interconnects and/or conductive pads to enable bonding and connection between conductive features in the bridge die 705, the IC structures 700-1, 700-2, and a circuit board. The IC structures 700-1 and 700-2 each include a stack of dies, and may be examples of the IC structure 100, discussed above. In the example illustrated in FIG. 7A, the IC structure 700-1 is a die stack that includes two dies 704-1, 704-2 bonded together with a hybrid bonding technique, as shown with an interface 716 between the dies 704-1 and 704-2. In the example illustrated in FIG. 7A, the IC structure 700-2 is a die stack that includes four dies 704-3, 704-4, 704-5, and 704-6 bonded together with conductive bumps 714. The dies 704-1, 704-2, 704-3, and 704-4 may include conductive pads 712 substantially aligned with and bonded with the conductive bumps 714. An insulator material 710 may also be present between adjacent dies of the IC structure 700-2 in a plane with the conductive bumps 714. In the example shown in FIG. 7A, the IC structures 700-1, 700-2 are bonded with the bridge die 705 via hybrid bonding interfaces 716. However, in other examples, different bonding techniques may be used to bond the IC structures 700-1, 700-2 with the bridge die 705 and/or to bond together adjacent dies of the IC structures 700-1, 700-2.

The method 600 continues with a process 604 of forming conductive vias through the dies or die stacks. The process 604 may be similar or the same as the process 404 discussed above. For example, forming conductive vias through the dies or die stacks may involve first forming openings through the dies or die stacks, and filling the openings with a conductive material. The assembly 750B of FIG. 7B is an example resulting assembly of the process of forming openings through the dies or die stacks. Forming the openings 760 may involve any suitable masking and etching techniques that enable etching through multiple layers of different materials, such as those discussed above. As can be seen in FIG. 7B, the assembly 750B includes openings 760 through the IC structures 700-1 and 700-2. The openings 760 extend through the dies of the IC structures 700-1, 700-2 and into the bridge die 705. In the example illustrated in FIG. 7B, the openings end at conductive elements 715, which may be, for example, conductive pads or interconnects. The openings 760 through the IC structure 700-2 extend through interfaces with conductive bumps (e.g., through inter-die interfaces with conductive bumps 714 between adjacent dies of the die stack of the IC structure 700-2). The openings 760 also extend through hybrid bonding interfaces 716 (e.g., through the hybrid bonding interface 716 between adjacent dies of the IC structure 700-1, and through the hybrid bonding interface 716 between the IC structures 700-1, 700-2 and the bridge die 705).

The assembly 750C of FIG. 7C is an example resulting assembly of the process of filling the openings 760. The assembly 750C includes conductive vias 708 through the IC structures 700-1 and 700-2 formed by filling the openings 760 with a conductive material 753. The electrically conductive material 753 may include any suitable electrically conductive material, such as any of those described above, and may be deposited using any suitable technique, such as those discussed above. As can be seen in FIG. 7C, the conductive vias 708 are coupled with conductive elements 715 in the bridge die.

The method 600 continues with the process 606 of providing a substrate over the dies or die stacks, and the process 608 of attaching the assembly (including the bridge die, dies or die stacks, and substrate) to a circuit board. The assembly 750D of FIG. 7D is an example resulting assembly of the process of providing a substrate over the dies or die stacks and attaching the assembly to a circuit board. As can be seen in FIG. 7D, the assembly 750D includes a substrate 702 over the IC structures 700-1, 700-2, and the assembly 766 (including the IC structures 700-1 and 700-2 between and bonded with the substrate 702 and the bridge die 705) is bonded with the circuit board 701 with a plurality of conductive bumps 714. The substrate 702 may be an example of the substrate 102, discussed above. In some examples, the substrate 702 may not be provided over the IC structures 700-1, 700-2 and bridge die 705. In some examples, an insulator material 755 may be included around, between, and/or over the IC structures 700-1, 700-2. The insulator material 755 may be an example of the insulator material 115 of FIG. 1A, discussed above.

Thus, FIGS. 4 and 6 illustrate methods 400 and 600 for fabricating microelectronic assemblies with a bridge die and through-assembly conductive vias. Performing the methods 400 or 600 may result in several features in the final assembly that are characteristic of the use of the methods 400 or 600. For example, one such feature characteristic of the use of the method 400 is illustrated in the assembly shown in FIG. 5E, in which the assembly 550E includes a circuit board 501, an interconnect structure (e.g., bridge die 505) over the circuit board 501, a plurality of IC structures over and bonded with the interconnect structure, where the plurality of IC structures includes a first IC structure 500-1 in a first plane substantially parallel with the circuit board 501 (e.g., in the x-y plane as shown in FIG. 5E, where the y-axis is going into and coming out of the page), where the first IC structure 500-1 includes one or more first dies 504-1, 504-2, and a second IC structure 500-2 in the first plane, where the second IC structure 500-2 includes one or more second dies 504-3-504-6, a first conductive via (e.g., the conductive via 508-2) through the first IC structure 500-1 and a second conductive via (e.g., the conductive via 508-5) through the second IC structure 500-2, where the first conductive via 508-2 and the second conductive via 508-5 taper in a direction away from the interconnect structure (e.g., away from the bridge die 505). For example, the conductive via 508-2 has a first portion/end with a first width 532 and a second portion/end with a second width 530 (where the first and second widths 532, 530 are dimensions of the conductive via 508-2 in a plane substantially parallel with the circuit board 501 and bridge die 505), where the first portion/end is closer to the bridge die 505 than the second portion/end, and where the first width 532 is greater than the second width 530. Another such feature is shown in FIG. 5E, in which one or more of the conductive vias 508-1-508-13 extend through the IC structures 500-1, 500-2 (e.g., through the die stacks, including through inter-die interfaces of the die stacks). Thus, in the example illustrated in FIG. 5E, portions of the conductive vias 508-1-508-13 proximate to the bridge die 505 are coplanar with the face or side of the IC structures that are bonded with the bridge die 505.

One feature characteristic of the use of the method 600 is illustrated in the assembly shown in FIG. 7D, in which the assembly 750D includes a circuit board 701, an interconnect structure (e.g., a bridge die 705) over the circuit board 701, a plurality of IC structures over and bonded with the interconnect structure, where the plurality of IC structures includes a first IC structure 700-1 including one or more first dies 704-1, 704-2, and a second IC structure 700-2 including one or more second dies 704-3-704-6, a first conductive via (e.g., the conductive via 708-1) through the one or more first dies and at least partially through the interconnect structure, and a second conductive via (e.g., the conductive via 708-2) through the one or more second dies and at least partially through the interconnect structure. Another such feature is shown in FIG. 7D, in which the conductive vias 708 taper in a direction towards the interconnect structure (e.g., towards the bridge die 705). For example, the conductive via 708-1 has a first portion/end with a first width 732 and a second portion/end with a second width 730 (where the first and second widths 732, 730 are dimensions of the conductive via 708-1 in a plane substantially parallel with the circuit board 701 and bridge die 705), where the first portion/end is closer to the bridge die 705 than the second portion/end, and where the first width 732 is smaller than the second width 730. The conductive vias 708 of FIG. 7D and the conductive vias 508-1-508-13 of FIG. 5E are formed through the assemblies, and may enable conductive paths between or amongst IC structures (e.g., between or amongst die stacks) with the through-assembly conductive vias and conductive interconnects in the bridge die and/or substrate.

IC devices, structures, and assemblies including a bridge die and through-assembly conductive vias as described herein (e.g., as described with reference to FIGS. 1A-1E, 2A-2F, 3A-3B, 4, 5A-5E, 6, and 7A-7D) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), a system including one or more of the aforementioned devices, etc.

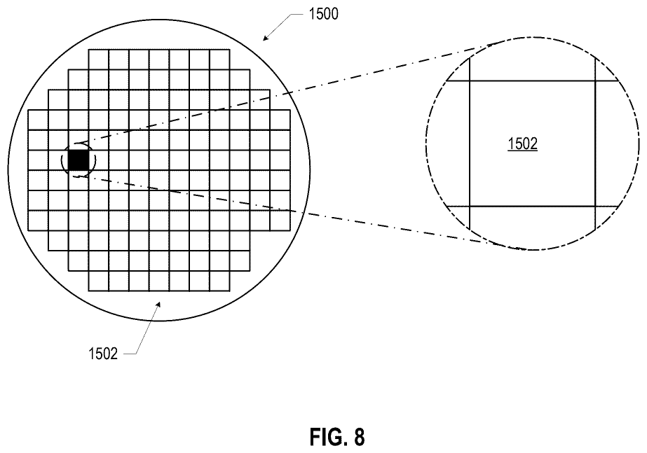

The devices, structures, and assemblies disclosed herein, e.g., the assemblies 150A, 160A, 166A, 150B, 160B, 166B, 160E, 250A, 266A, 250B, 266B, 250C, 266C, 250D, 266D, 250E, 266E, 250F, 266F, 366A, 366B, 550E, 750D, or any variations thereof, may be included in any suitable electronic component. FIGS. 8-11 illustrate various examples of apparatuses that may include any of the IC structures or assemblies disclosed herein.

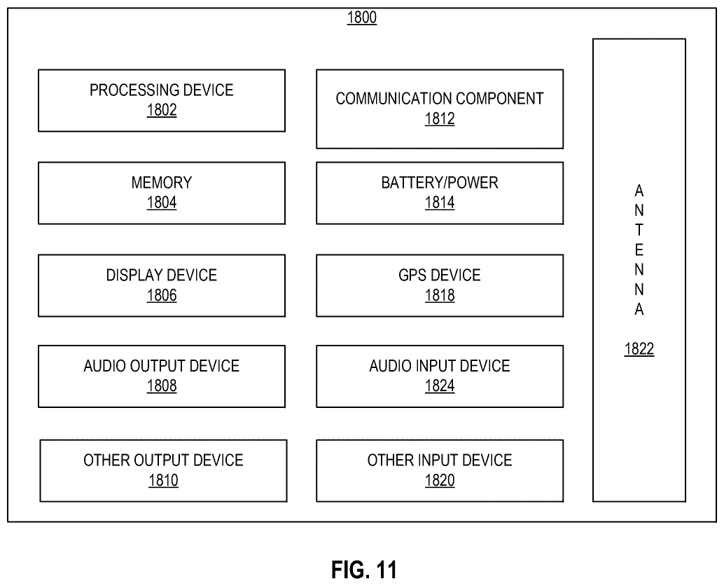

FIG. 8 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the structures and/or dies, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 11 is a side, cross-sectional view of an example IC package 1650 that may include one or more IC structures in accordance with any of the embodiments disclosed herein (e.g., any of the assemblies 150A, 160A, 166A, 150B, 160B, 166B, 160E, 250A, 266A, 250B, 266B, 250C, 266C, 250D, 266D, 250E, 266E, 250F, 266F, 366A, 366B, 550E, 750D, or any variations thereof described herein, or any combination). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

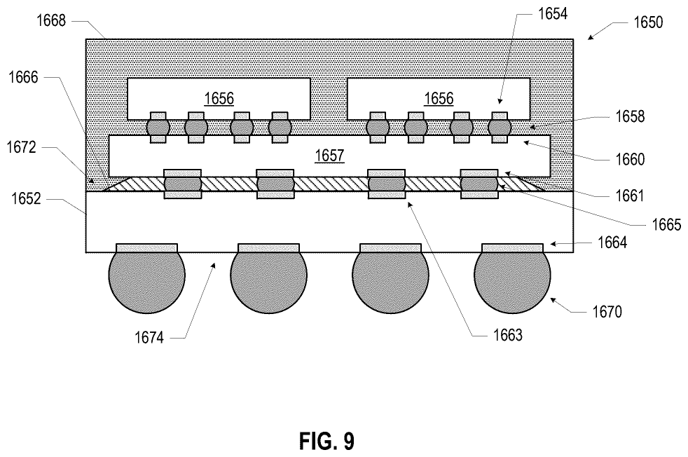

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 9 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 9 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 9 are solder balls (e.g., for a BGA arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 8.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 9 is a flip chip package, other package architectures may be used. For example, the IC package 1650 may be a BGA package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 9, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

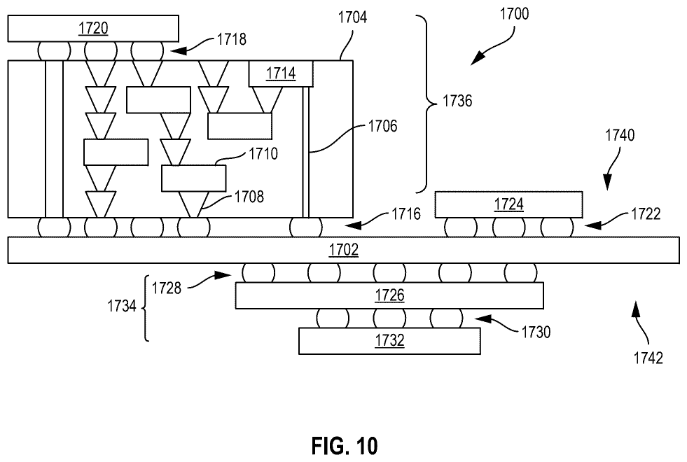

FIG. 10 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 9 (e.g., may include one or more of assemblies 150A, 160A, 166A, 150B, 160B, 166B, 160E, 250A, 266A, 250B, 266B, 250C, 266C, 250D, 266D, 250E, 266E, 250F, 266F, 366A, 366B, 550E, 750D, or any variations thereof described herein, or any combination of such structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 8), an IC device, an assembly (e.g., one or more of assemblies 150A, 160A, 166A, 150B, 160B, 166B, 160E, 250A, 266A, 250B, 266B, 250C, 266C, 250D, 266D, 250E, 266E, 250F, 266F, 366A, 366B, 550E, 750D, or any variations thereof described herein, or any combination of such structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 10, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides a microelectronic assembly including a first IC structure (e.g., a bridge die), where the first IC structure includes a plurality of interconnect layers; a second IC structure (e.g., a substrate) over the first IC structure; a first die and a second die in a plane substantially parallel with the first IC structure between the first IC structure and the second IC structure, where the first die includes a first face bonded with the first IC structure and the second die includes a second face bonded with the first IC structure; a first conductive via through the first die and coupled with a first conductive interconnect of the plurality of interconnect layers, where the first conductive via includes a first portion that is coplanar with the first face; and a second conductive via through the second die and coupled with a second conductive interconnect of the plurality of interconnect layers, where the second conductive via includes a second portion that is coplanar with the second face.

Example 2 provides the microelectronic assembly of example 1, where: the first IC structure includes a conductive path between the first conductive via and the second conductive via.

Example 3 provides the microelectronic assembly of example 1 or 2, where: the second IC structure includes a conductive path between the first conductive via and the second conductive via.

Example 4 provides the microelectronic assembly of any one of examples 1-3, further including a first die stack including the first die; and a second die stack including the second die, where: the first conductive via is through the first die stack, and the second conductive via is through the second die stack.

Example 5 provides the microelectronic assembly of any one of examples 1-4, further including a plurality of conductive bumps between the first IC structure and the first die, where: the first portion of the first conductive via is coupled with one of the plurality of conductive bumps, and the first portion has a larger width than another portion of the first conductive via that is further from the first IC structure than the first portion (e.g., the first conductive via tapers away from the first IC structure).

Example 6 provides the microelectronic assembly of any one of examples 1-5, where: the first portion of the conductive via is bonded with a first conductive pad of the first IC structure (e.g., the die stack is hybrid bonded with the first IC structure), and the first portion has a larger width than another portion of the first conductive via that is further from the first IC structure than the first portion (e.g., the first conductive via tapers away from the first IC structure).

Example 7 provides the microelectronic assembly of example 4, where: the first die stack has a further face opposite the first face, the further face is bonded with the second IC structure, and the first conductive via extends from the further face into the first IC structure.

Example 8 provides the microelectronic assembly of example 7, where: the first portion has a smaller width than another portion of the first conductive via that is further from the first IC structure than the first portion (e.g., the conductive via tapers towards the first IC structure).

Example 9 provides the microelectronic assembly of any one of examples 1-8, further including a third conductive via through the first die and coupled with a third conductive interconnect of the first IC structure, where: the third conductive via includes a third portion that is coplanar with the first face, and the third conductive via and the first conductive via taper in opposite directions.

Example 10 provides the microelectronic assembly of any one of examples 1-9, where: the first conductive via extends through at least one interface with conductive bumps.

Example 11 provides the microelectronic assembly of example 10, where: the interface with conductive bumps is between the first die and a further die stacked over the first die.

Example 12 provides the microelectronic assembly of example 10 or 11, where: the interface with conductive bumps is between the first die and the first IC structure.

Example 13 provides the microelectronic assembly of any one of examples 1-12, where: the first IC structure is over and bonded with a circuit board.

Example 14 provides a microelectronic assembly including an interconnect structure (e.g., a bridge die) including a plurality of conductive contacts on a first side (e.g., for coupling with a circuit board); a plurality of IC structures over and bonded with a second side of the interconnect structure, where the plurality of IC structures includes a first IC structure including one or more first dies, and a second IC structure including one or more second dies; a first conductive via through the one or more first dies and at least partially through the interconnect structure; a second conductive via through the one or more second dies and at least partially through the interconnect structure; and a conductive interconnect in the interconnect structure coupled with the first conductive via and the second conductive via.

Example 15 provides the microelectronic assembly of example 14, further including a substrate over and bonded with the plurality of IC structures.

Example 16 provides the microelectronic assembly of example 15, where: the interconnect structure is a first interconnect structure, the conductive interconnect is a first conductive interconnect, and the substrate is a second interconnect structure including a second conductive interconnect coupled with conductive vias in the first IC structure and the second IC structure.

Example 17 provides the microelectronic assembly of any one of examples 14-16, where: the first conductive via includes a first portion in the interconnect structure, where the first portion has a first width, and where the first width is a dimension of the first conductive via in a plane substantially parallel to the interconnect structure, and a second portion opposite to the first portion, where the second portion has a second width, and where the second width is a dimension of the conductive via in the plane, where the first width is smaller than the second width.

Example 18 provides the microelectronic assembly of any one of examples 14-17, further including a plurality of conductive bumps between the first IC structure and the interconnect structure; and an insulator material between the first IC structure and the interconnect structure and coplanar with the plurality of conductive bumps, where the first conductive via extends through the insulator material.

Example 19 provides a microelectronic assembly including an interconnect structure including a plurality of conductive contacts on a first side; a plurality of IC structures over and bonded with a second side of the interconnect structure, where the plurality of IC structures includes a first IC structure in a first plane substantially parallel with the interconnect structure, where the first IC structure includes one or more first dies, and a second IC structure in the first plane, where the second IC structure includes one or more second dies; a first conductive via through the first IC structure; a second conductive via through the second IC structure, where the first conductive via and the second conductive via taper in a direction away from the interconnect structure; and a conductive interconnect in the interconnect structure coupled with the first conductive via and the second conductive via.

Example 20 provides the microelectronic assembly of example 19, further including a plurality of conductive bumps between the interconnect structure and the first IC structure, where: a portion of the first conductive via is bonded with one of the plurality of conductive bumps.

Example 21 provides the microelectronic assembly according to any one of examples 1-20, where the microelectronic assembly includes or is a part of a central processing unit.

Example 22 provides the microelectronic assembly according to any one of examples 1-21, where the microelectronic assembly includes or is a part of a memory device.

Example 23 provides the microelectronic assembly according to any one of examples 1-22, where the microelectronic assembly includes or is a part of a logic circuit.

Example 24 provides the microelectronic assembly according to any one of examples 1-23, where the microelectronic assembly includes or is a part of input/output circuitry.

Example 25 provides the microelectronic assembly according to any one of examples 1-24, where the microelectronic assembly includes or is a part of a field programmable gate array transceiver.

Example 26 provides the microelectronic assembly according to any one of examples 1-25, where the microelectronic assembly includes or is a part of a field programmable gate array logic.

Example 27 provides the microelectronic assembly according to any one of examples 1-26, where the microelectronic assembly includes or is a part of a power delivery circuitry.

Example 28 provides an IC package that includes a microelectronic assembly according to any one of examples 1-20.

Example 29 provides the IC package according to example 28, further including a further IC component coupled to the microelectronic assembly.

Example 30 provides the IC package according to example 29, where the further IC component includes a package substrate.

Example 31 provides the IC package according to example 29, where the further IC component includes an interposer.

Example 32 provides the IC package according to example 29, where the further IC component includes a further assembly or die.

Example 33 provides a computing device that includes a carrier substrate and an assembly coupled to the carrier substrate, where the assembly is an assembly according to any one of examples 1-20, or the assembly is included in the IC package according to any one of examples 28-32.

Example 34 provides the computing device according to example 33, where the computing device is a wearable or handheld computing device.

Example 35 provides the computing device according to examples 33 or 34, where the computing device further includes one or more communication chips.

Example 36 provides the computing device according to any one of examples 33-35, where the computing device further includes an antenna.

Example 37 provides the computing device according to any one of examples 33-36, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly comprising:
a first integrated circuit (IC) structure, wherein the first IC structure comprises a plurality of interconnect layers;
a second IC structure over the first IC structure;
a first die and a second die in a plane substantially parallel with the first IC structure between the first IC structure and the second IC structure, wherein the first die comprises a first face bonded with the first IC structure and the second die comprises a second face bonded with the first IC structure;
a first conductive via through the first die and coupled with a first conductive interconnect of the plurality of interconnect layers, wherein the first conductive via comprises a first portion that is coplanar with the first face; and
a second conductive via through the second die and coupled with a second conductive interconnect of the plurality of interconnect layers, wherein the second conductive via comprises a second portion that is coplanar with the second face.

2. The microelectronic assembly of claim 1, wherein:
the first IC structure comprises a conductive path between the first conductive via and the second conductive via.

3. The microelectronic assembly of claim 1, wherein:
the second IC structure comprises a conductive path between the first conductive via and the second conductive via.

4. The microelectronic assembly of claim 1, further comprising:
a first die stack comprising the first die; and
a second die stack comprising the second die, wherein:
the first conductive via is through the first die stack, and the second conductive via is through the second die stack.

5. The microelectronic assembly of claim 1, further comprising:
a plurality of conductive bumps between the first IC structure and the first die, wherein:
the first portion of the first conductive via is coupled with one of the plurality of conductive bumps, and
the first portion has a larger width than another portion of the first conductive via that is further from the first IC structure than the first portion.

6. The microelectronic assembly of claim 1, wherein:
the first portion of the conductive via is bonded with a first conductive pad of the first IC structure, and
the first portion has a larger width than another portion of the first conductive via that is further from the first IC structure than the first portion.

7. The microelectronic assembly of claim 4, wherein:
the first die stack has a further face opposite the first face,
the further face is bonded with the second IC structure, and
the first conductive via extends from the further face into the first IC structure.

8. The microelectronic assembly of claim 7, wherein:
the first portion has a smaller width than another portion of the first conductive via that is further from the first IC structure than the first portion.

9. The microelectronic assembly of claim 1, further comprising:
a third conductive via through the first die and coupled with a third conductive interconnect of the first IC structure, wherein:
the third conductive via comprises a third portion that is coplanar with the first face, and
the third conductive via and the first conductive via taper in opposite directions.

10. The microelectronic assembly of claim 1, wherein:
the first conductive via extends through at least one interface with conductive bumps.

11. The microelectronic assembly of claim 10, wherein:
the interface with conductive bumps is between the first die and a further die stacked over the first die.

12. The microelectronic assembly of claim 10, wherein:
the interface with conductive bumps is between the first die and the first IC structure.

13. The microelectronic assembly of claim 1, wherein:
the first IC structure is over and bonded with a circuit board.

14. A microelectronic assembly comprising:
an interconnect structure comprising a plurality of conductive contacts on a first side;
a plurality of integrated circuit (IC) structures over and bonded with a second side of the interconnect structure, wherein the plurality of IC structures comprises:
a first IC structure comprising one or more first dies, and
a second IC structure comprising one or more second dies;
a first conductive via through the one or more first dies and at least partially through the interconnect structure;
a second conductive via through the one or more second dies and at least partially through the interconnect structure; and
a conductive interconnect in the interconnect structure coupled with the first conductive via and the second conductive via.

15. The microelectronic assembly of claim 14, further comprising:
a substrate over and bonded with the plurality of IC structures.

16. The microelectronic assembly of claim 15, wherein:
the interconnect structure is a first interconnect structure, the conductive interconnect is a first conductive interconnect, and
the substrate is a second interconnect structure comprising a second conductive interconnect coupled with conductive vias in the first IC structure and the second IC structure.

17. The microelectronic assembly of claim 14, wherein:
the first conductive via comprises:
a first portion in the interconnect structure, wherein the first portion has a first width, and wherein the first width is a dimension of the first conductive via in a plane substantially parallel to the interconnect structure, and
a second portion opposite to the first portion, wherein the second portion has a second width, and wherein the second width is a dimension of the conductive via in the plane, wherein the first width is smaller than the second width.

18. The microelectronic assembly of claim 14, further comprising:
a plurality of conductive bumps between the first IC structure and the interconnect structure; and
an insulator material between the first IC structure and the interconnect structure and coplanar with the plurality of conductive bumps, wherein the first conductive via extends through the insulator material.

19. A microelectronic assembly comprising:
an interconnect structure comprising a plurality of conductive contacts on a first side;
a plurality of integrated circuit (IC) structures over and bonded with a second side of the interconnect structure, wherein the plurality of IC structures comprises:
a first IC structure in a first plane substantially parallel with the interconnect structure, wherein the first IC structure comprises one or more first dies, and
a second IC structure in the first plane, wherein the second IC structure comprises one or more second dies;
a first conductive via through the first IC structure;
a second conductive via through the second IC structure, wherein the first conductive via and the second conductive via taper in a direction away from the interconnect structure; and
a conductive interconnect in the interconnect structure coupled with the first conductive via and the second conductive via.

20. The microelectronic assembly of claim 19, further comprising:
a plurality of conductive bumps between the interconnect structure and the first IC structure, wherein:
a portion of the first conductive via is bonded with one of the plurality of conductive bumps.
